(19) United States
(12) Patent Application Publication
(10) Pub. No.: US 2025/0393433 A1
(43) Pub. Date: Dec. 25, 2025

(54) DISPLAY DEVICE AND METHOD FOR MANUFACTURING THE SAME

(71) Applicant: Samsung Display Co., LTD., Yongin-si (KR)

(72) Inventors: Jin Won KIM, Yongin-si (KR); Sun Young KWON, Yongin-si (KR); Bu Yong KIM, Yongin-si (KR); Hye Jin PAEK, Yongin-si (KR)

(21) Appl. No.: 19/069,019

(22) Filed: Mar. 3, 2025

(30) Foreign Application Priority Data
Jun. 21, 2024 (KR) 10-2024-0080789

(51) Int. Cl. H10K 59/38; H10K 59/12; H10K 59/122; H10K 59/80

(52) U.S. Cl. CPC H10K 59/38; H10K 59/1201; H10K 59/122; H10K 59/8792

(57) ABSTRACT

A display device is provided. The display device may include a first substrate including light emitting elements and a second substrate opposite to the first substrate. The emission areas may include a first emission area, a second emission area, and a third emission area. The second substrate may include a second support substrate opposite to the first substrate, a color filter layer on one surface of the second support substrate, and a color conversion layer on the color filter layer. The color conversion layer may include a bank portion in a non-emission area between the emission areas. The bank portion may include a first bank having a first thickness and a second bank having a second thickness that is less than the first thickness in at least a part of the non-emission area between the first emission area and the third emission area.

### CROSS-REFERENCE TO RELATED APPLICATION

The present application claims priority to and the benefit of Korean Patent Application No. 10-2024-0080789, filed on Jun. 21, 2024, in the Korean Intellectual Property Office, the entire content of which is incorporated herein by reference.

### BACKGROUND

### 1. Field

One or more embodiments of the present disclosure relate to a display device and a method for manufacturing the display device.

### 2. Description of the Related Art

In an increasingly information-driven society, there is a growing demand for display devices capable of presenting images in one or more suitable formats. These display devices are integrated into a range of electronic equipment, including but not limited to smartphones, digital cameras, laptop computers, navigation systems, and/or smart televisions.

The display device may be a flat panel display device, such as a liquid crystal display device, a field emission display device, and/or a light emitting display device. Examples of the light emitting display device may include (encompass) light-emitting display devices encompass organic light-emitting displays (OLEDs) that utilize organic light-emitting elements, inorganic light-emitting displays that incorporate inorganic semiconductor elements, and/or micro light-emitting displays featuring micro light-emitting elements.

The organic light emitting display device generates (displays) images

through light-emitting elements, each including a light-emitting layer made from organic materials. This self-emissive characteristic of organic light-emitting displays typically results in enhanced performance metrics, including lower power consumption, faster response times, higher luminous efficiency, increased luminance, and wider viewing angles compared to other display technologies.

The display surface of the display device, which emits light, includes (or has) a display area designed for image presentation and a surrounding non-display area. The display area contains emission regions that emit light at one or more luminance levels and colors.

### SUMMARY

The display device may include a first substrate that emits light of emission areas with respective luminances and a second substrate that converts the light of the emission areas into respective colors.

The second substrate may include a color conversion layer that converts or transmits light emitted from the first substrate into light of another wavelength band and a color filter layer that selectively transmits light emitted from the color conversion layer.

The color conversion layer may include an ink material that converts a wavelength band of light.

A process of providing the color conversion layer may include an ink ejection process that partially ejects the ink material.

Therefore, the width of the emission areas is desired or required to be greater than a minimum margin of the ink ejection process, which causes a problem that realization of high resolution of the display device is limited.

For example, the display device may include a first substrate that emits light in specific emission areas with varying luminances, and a second substrate that modifies this emitted light into different wavelength bands. The second substrate may include a color conversion layer, which may use an ink material to alter the light's wavelength, and a color filter layer that selectively transmits the modified light. However, the process of applying the color conversion layer involves partially ejecting the ink material, necessitating that the emission areas be wider than the minimum margin of the ink ejection process. This requirement poses a challenge to achieving high resolution in the display device.

One or more aspects of embodiments of the present disclosure are directed toward a display device that is advantageous or beneficial in realizing or providing relatively high resolution because the width of the emission areas may become less than the minimum margin of the ink ejection process. For example, one or more aspects of the embodiments of the present disclosure are directed toward a display device that is capable of achieving high resolution, as the width of the emission areas may be reduced to less than the minimum margin required by the ink ejection process.

However, aspects and features of embodiments of the present disclosure are not restricted to the one set forth herein. The above and other aspects and features of certain embodiments of the present disclosure will become more apparent to one of ordinary skill in the art to which the present disclosure pertains by referencing the detailed description of the present disclosure given.

One or more embodiments of the present disclosure provide a display device that includes a first substrate including light emitting elements in emission areas on a first support substrate; a second substrate that is opposite to (e.g., faces) the first substrate; and a filling layer between the first substrate and the second substrate. The emission areas include a first emission area that is to emit light of a first wavelength band; a second emission area that is to emit light of a second wavelength band, wherein the second wavelength band is lower than the first wavelength band; and a third emission area that is to emit light of a third wavelength band, wherein the third wavelength band is lower than the second wavelength band. The light emitting elements are to emit light of a fourth wavelength band, wherein the fourth wavelength band is lower than or equal to the third wavelength band. The second substrate includes a second support substrate that is opposite to (e.g., faces) the first substrate; a color filter layer on one surface of the second support substrate; and a color conversion layer on the color filter layer. The color conversion layer includes a bank portion in a non-emission area between the emission areas (e.g., between the first emission area and the second emission area, between the first emission area and the third emission area, and/or between the second emission area and the third emission area). The bank portion includes a first bank having a first thickness; and a second bank having a second thickness that is less than the first thickness in at least a part of the non-emission area between the first emission area and the third emission area. For example, the color conversion layer features a bank portion located in the non-emission areas between the emission regions (e.g., between the first and second emission areas, the first and third emission areas, and/or the second and third emission areas). This bank portion may include a first bank with a certain (e.g., set or predetermined) thickness and a second bank with a reduced thickness in at least part of the non-emission area between the first emission area and third emission area.

The color filter layer may include a light blocking portion in the non-emission area, wherein the light blocking portion may be to block light; a first filter portion in the first emission area, wherein the first filter portion may be to transmit light of the first wavelength band; a second filter portion in the second emission area, wherein the second filter portion may be to transmit light of the second wavelength band; and a third filter portion in the third emission area, wherein the third filter portion may be to transmit light of the third wavelength band. The color conversion layer may further include a first color conversion portion in the first emission area, wherein the first color conversion portion may be to convert the light of the fourth wavelength band into light of the first wavelength band; and a light transmitting portion in at least a part of the third emission area, wherein the light transmitting portion may be to transmit light of the fourth wavelength band. The bank portion may be around (e.g., surround) a periphery of each of the first color conversion portion and the light transmitting portion. A part of the light transmitting portion between the first bank and the second bank may have a thickness that varies from the first thickness to the second thickness (e.g., a thickness between the first thickness and the second thickness). A surface of each of the light transmitting portion and the bank portion may have a hydrophobic property (e.g., a water-repelling property and/or a water-resistant property).

The third emission area may include a first divided area on one side and a second divided area on the other side in a direction that cross (e.g., intersect) a direction in which the first emission area and the third emission area are opposite to (e.g., face) each other. The second bank may be between the first emission area and the first divided area.

The color conversion layer may further include a spacer that extends in the direction in which the first emission area and the third emission area are opposite to (e.g., face) each other and that crosses (e.g., intersects) the third emission area. The first divided area may be adjacent to one side of the spacer. The second divided area may be adjacent to the other side of the spacer.

The bank portion may further include a third bank having the first thickness between the first divided area and the second divided area. The spacer may be on the first bank and the third bank.

The third emission area may further include a third divided area between the first divided area and the second divided area. The spacer may be on a part of the third divided area in the light transmitting portion.

The color conversion layer may further include a second color conversion portion in the second emission area, wherein the second color conversion portion may be to convert the light of the fourth wavelength band into light of the second wavelength band. The bank portion may further include a fourth bank having the second thickness between the second emission area and the second divided area. A part of the light transmitting portion between the first bank and the fourth bank may have a thickness that varies from the first thickness to the second thickness (e.g., a thickness between the first thickness and the second thickness).

The color conversion layer may further include an additional light transmitting portion in the second emission area, wherein the additional light transmitting portion may be to transmit light of the fourth wavelength band. A surface of the additional light transmitting portion may have a hydrophobic property (e.g., a water-repelling property and/or a water-resistant property).

In the direction in which the first emission area and the third emission area are opposite to (e.g., face) each other, the third emission area may be between the first emission area and the second emission area.

In the direction that crosses (e.g., intersects) the direction in which the first emission area and the third emission area are opposite to (e.g., face) each other, the first emission area and the second emission area may be adjacent to each other. In the direction in which the first emission area and the third emission area are opposite to (e.g., face) each other, the third emission area may further be opposite to (e.g., may face) the second emission area.

The second substrate may further include a first capping layer that is to cover the color filter layer and a second capping layer that is to cover the color conversion layer.

The first substrate may include a circuit layer on the first support substrate, wherein the circuit layer may include light emitting pixel drivers that are electrically connected to the light emitting elements, respectively; an element layer on the circuit layer, and wherein the element layer may include the light emitting elements; and an encapsulation layer that covers the element layer. The element layer may include anode electrodes in the emission areas; a pixel defining layer in the non-emission area, wherein the pixel defining layer may cover an edge of the anode electrodes; a light emitting layer on the anode electrodes and the pixel defining layer; and a cathode electrode on the light emitting layer. Each of the light emitting elements may include a structure in which a light emitting layer is between an anode electrode and a cathode electrode that are opposite to (e.g., face) each other.

One or more embodiments of the present disclosure provide a method for manufacturing a display device, the method includes preparing a first substrate including light emitting elements in emission areas (e.g., a first emission area, a second emission area, a third emission area, and/or the like); preparing a second substrate including a color filter layer and a color conversion layer; providing (applying) a filling layer on the first substrate and/or the second substrate; and aligning and bonding the first substrate and the second substrate. The preparing of the second substrate includes providing (applying) the color filter layer on a second support substrate; providing (applying) a first capping layer that covers the color filter layer; providing (applying) the color conversion layer on the first capping layer; and providing (applying) a second capping layer that covers the color conversion layer. The providing of the color conversion layer includes providing a bank portion in a non-emission area between the emission areas (e.g., between the first emission area and the second emission area, between the first emission area and the third emission area, and/or between the second emission area and the third emission area). The providing of the bank portion includes exposing a bank material layer on the first capping layer by utilizing a first mask and developing the bank material layer. In the exposing of the bank material layer, the first mask includes a first blocking portion that is opposite to (e.g., faces) the emission areas; a first transmitting portion that is opposite to (e.g., faces) a part of the non-emission area, wherein the first transmitting portion is to transmit light; and a first semi-transmitting portion that is opposite to (e.g., faces) another part of the non-emission area, wherein the first semi-transmitting portion is to transmit a smaller amount of light than the first transmitting portion. In the developing of the bank material layer, the bank portion having a hydrophobic surface (e.g., a surface having a water-repelling property and/or a water-resistant property) is provided. The bank portion includes a first bank that is opposite to (e.g., faces) the first transmitting portion and that has a first thickness; and a second bank that is opposite to (e.g., faces) the first semi-transmitting portion and that has a second thickness that is less than the first thickness.

The emission areas may include a first emission area that is to emit light of a first wavelength band; a second emission area that is to emit light of a second wavelength band, wherein the second wavelength band may be lower than the first wavelength band; and a third emission area that is to emit light of a third wavelength band, wherein the third wavelength band may be lower than the second wavelength band. The third emission area may include a first divided area on one side and a second divided area on the other side in a direction that crosses (e.g., intersects) a direction in which the first emission area and the third emission area are opposite to (e.g., face) each other. The light emitting elements may be to emit light of a fourth wavelength band, wherein the fourth wavelength band may be lower than or equal to the third wavelength band. In the providing of the color filter layer, the color filter layer may include a light blocking portion in the non-emission area, wherein the light blocking portion may be to block light; a first filter portion in the first emission area, wherein the first filter portion may be to transmit light of the first wavelength band; a second filter portion in the second emission area, wherein the second filter portion may be to transmit light of the second wavelength band; and a third filter portion in the third emission area, wherein the third filter portion may be to transmit light of the third wavelength band. In the providing of the bank portion, the second bank may be between the first emission area and the first divided area. The providing of the color conversion layer may include providing a light transmitting portion that is to transmit light of the fourth wavelength band in the third emission area; and providing a first color conversion portion that is to convert the light of the fourth wavelength band into light of the first wavelength band in the first emission area. In the providing of the light transmitting portion, a part of the light transmitting portion between the first bank and the second bank may have an inclined top surface.

In the providing of the light transmitting portion, a surface of the light transmitting portion may have a hydrophobic property (e.g., a water-repelling property and/or a water-resistant property). The providing of the first color conversion portion may include dropping a first ink material in a first drop area including a part of the first emission area that is adjacent to one side of the second bank, the first divided area, and the second bank; causing a part of the first ink material dropped on the second bank and the light transmitting portion to flow to the first emission area due to (e.g., by using) the inclined top surface of the light transmitting portion and a hydrophobic property (e.g., a water-repelling property and/or a water-resistant property) of a surface of each of the second bank and the light transmitting portion; and providing the first color conversion portion by curing the first ink material in the first emission area.

In the causing of the part of the first ink material to flow to the first emission area, the second support substrate may be tilted.

In the providing of the bank portion, the first mask may further include a second transmitting portion that extends in the direction in which the first emission area and the third emission area are opposite to (e.g., face) each other and that crosses (e.g., intersects) the third emission area. The bank portion may further include a third bank that is opposite to (e.g., faces) the second transmitting portion and that has the first thickness. The first divided area may be adjacent to one side of the third bank. The second divided area may be adjacent to the other side of the third bank. The providing of the light transmitting portion may include exposing a light transmitting material layer that covers the first capping layer and the bank portion by utilizing a second mask; and developing the light transmitting material layer. In the exposing of the light transmitting material layer, the second mask may include a second blocking portion that is opposite to (e.g., faces) the first emission area, the second emission area, and the non-emission area and that is to block light; a third transmitting portion that is opposite to (e.g., faces) the first divided area and the second divided area; and a fourth transmitting portion that is opposite to (e.g., faces) the third bank. In the developing of the light transmitting material layer, the light transmitting portion that is opposite to (e.g., faces) the third transmitting portion and a spacer that is opposite to (e.g., faces) the fourth transmitting portion may be provided. Each of the light transmitting portion and the spacer may have a hydrophobic surface (e.g., a surface having a water-repelling property and/or a water-resistant property).

In the providing of the bank portion, the first mask may further include a second semi-transmitting portion that is opposite to (e.g., faces) a part of the non-emission area between the second emission area and the second divided area. The bank portion may further include a fourth bank that is opposite to (e.g., faces) the second semi-transmitting portion and that has the second thickness. The providing of the color conversion layer may further include providing a second color conversion portion that is to convert the light of the fourth wavelength band into light of the second wavelength band in the second emission area. In the providing of the light transmitting portion, another part of the light transmitting portion between the first bank and the fourth bank may have an inclined top surface. The providing of the second color conversion portion may include dropping a second ink material in a second drop area including a part of the second emission area that is adjacent to one side of the fourth bank, the second divided area, and the fourth bank; causing a part of the second ink material dropped on the fourth bank and the light transmitting portion to flow to the second emission area due to (e.g., by using) the inclined top surface of the light transmitting portion and a hydrophobic property (e.g., a water-repelling property and/or a water-resistant property) of a surface of each of the fourth bank and the light transmitting portion; and providing the second color conversion portion by curing the second ink material in the second emission area.

The providing of the light transmitting portion may include exposing a light transmitting material layer that covers the first capping layer and the bank portion by utilizing a second mask; and developing the light transmitting material layer. In the exposing of the light transmitting material layer, the second mask may include a second blocking portion that is opposite to (e.g., faces) the first emission area and the non-emission area and that is to block light; a third transmitting portion that is opposite to (e.g., faces) the third emission area; and a fifth transmitting portion that is opposite to (e.g., faces) the second emission area. In the developing of the light transmitting material layer, the light transmitting portion that is opposite to (e.g., faces) the third transmitting portion and an additional light transmitting portion that is opposite to (e.g., faces) the fifth transmitting portion may be provided. Each of the light transmitting portion and the additional light transmitting portion may have a hydrophobic surface (e.g., a surface having a water-repelling property and/or a water-resistant property).

The third emission area may further include a third divided area between the first divided area and the second divided area. The providing of the color conversion layer may further include, after the providing of the light transmitting portion, providing a spacer that extends in the direction in which the first emission area and the third emission area are opposite to (e.g., face) each other and that overlaps the third divided area. The providing of the light transmitting portion may include exposing a light transmitting material layer that covers the first capping layer and the bank portion by utilizing a second mask; and developing the light transmitting material layer. In the exposing of the light transmitting material layer, the second mask may include a third transmitting portion that is opposite to (e.g., faces) the third emission area; and a second blocking portion in a remaining part except the third emission area. In the developing of the light transmitting material layer, the light transmitting portion that is opposite to (e.g., faces) the third transmitting portion may be provided. The providing of the spacer may include removing a remaining part of a spacer material layer that covers the light transmitting portion except a part of the remaining part of the spacer material layer that overlaps the third divided area. The spacer may extend to the first bank.

The display device according to one or more embodiments may include a first substrate that includes light emitting elements in emission areas and a second substrate that is opposite to (e.g., faces) the first substrate that includes the color conversion layer. The color conversion layer may include a bank portion in a non-emission area between the emission areas (e.g., between the first emission area and the second emission area, between the first emission area and the third emission area, and/or between the second emission area and the third emission area). The bank portion may include a first bank having a first thickness and a second bank having a second thickness that is less than the first thickness in a part of the non-emission area.

The emission areas may include a first emission area that is to emit light of a first wavelength band, a second emission area that is to emit light of a second wavelength band that may be lower than the first wavelength band, and a third emission area that is to emit light of a third wavelength band that may be lower than the second wavelength band.

The light emitting elements may be to emit light of a fourth wavelength band that may be lower than or equal to the third wavelength band.

According to one or more embodiments, the color conversion layer may further include a first color conversion portion that is in the first emission area and that is to convert the light of the fourth wavelength band into light of the first wavelength band, and a light transmitting portion that is in the third emission area and that is to transmit light of the fourth wavelength band.

A part of the light transmitting portion between the first bank and the second bank may have a thickness that varies from the first thickness to the second thickness (e.g., a thickness between the first thickness and the second thickness).

The surface of each of the bank portion and the light transmitting portion may have a hydrophobic property (e.g., a water-repelling property and/or a water-resistant property).

In one or more embodiments, in the arrangement process of the first color conversion portion, a first ink material dropped on the second bank and a part of the light transmitting portion between the first bank and the second bank may relatively easily flow to the first emission area due to the partially inclined surface of the light transmitting portion that is caused by the variable or substantially different thickness and the hydrophobic property (e.g., a water-repelling property and/or a water-resistant property) of each of the bank portion and the light transmitting portion.

In one or more embodiments, a first drop area where the first ink material is dropped is not limited to the first emission area and may extend to a part of the light transmitting portion in the third emission area and the second bank in the non-emission area. For example, the width of the first emission area may become less than the minimum margin of the ink ejection process as well as the width of the first drop area. Therefore, the display device according to one or more embodiments may be advantageous or beneficial in realizing or providing relatively high resolution.

One or more embodiments of the present disclosure provide an electronic device that includes the display device as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

However, aspects and features of embodiments of the present disclosure are not limited to those above. One or more other suitable aspects and features may also be incorporated herein.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is a plan view illustrating a display device according to one or more embodiments;

FIG. 2 is a cross-sectional view taken along the line A-A′ of FIG. 1 according to one or more embodiments;

FIG. 3 is a layout diagram illustrating a display area and a color conversion layer of part B of FIG. 1 according to one or more embodiments;

FIG. 4 is a block diagram illustrating a circuit layer of part B of FIG. 1 according to one or more embodiments;

FIG. 5 is an equivalent circuit diagram illustrating the light emitting pixel driver of FIG. 4 according to one or more embodiments;

FIG. 6 is a cross-sectional view taken along the line C-C′ of FIG. 3 according to one or more embodiments;

FIG. 7 is a cross-sectional view taken along the line D-D′ of FIG. 3 according to one or more embodiments;

FIG. 8 is a cross-sectional view taken along the line E-E′ of FIG. 3 according to one or more embodiments;

FIG. 9 is a cross-sectional view taken along the line F-F′ of FIG. 3 according to one or more embodiments;

FIG. 10 is a flowchart illustrating a method for manufacturing the display device according to one or more embodiments;

FIG. 11 is a flowchart illustrating steps (e.g., acts or tasks) of preparing the second substrate of FIG. 10 according to one or more embodiments;

FIG. 12 is a flowchart illustrating steps (e.g., acts or tasks) of providing the color conversion layer of FIG. 11 according to one or more embodiments;

FIGS. 13, 14, 15, 16, 17, 18, 19, 20, 21, 22, 23, 24, 25, 26, 27, 28, and 29 are process views illustrating one or more steps (e.g., acts or tasks) of FIGS. 10, 11, and 12 according to one or more embodiments of FIG. 9;

FIG. 30 is a cross-sectional view taken along the line F-F′ of FIG. 3 according to one or more embodiments;

FIGS. 31 and 32 are process views illustrating one or more steps (e.g., acts or tasks) of FIG. 12 according to one or more embodiments of FIG. 30;

FIG. 33 is a plan view illustrating a display area and a color conversion layer of part B of FIG. 1 according to one or more embodiments;

FIG. 34 is a cross-sectional view taken along the line G-G′ of FIG. 33 according to one or more embodiments;

FIGS. 35, 36, 37, 38, and 39 are process views illustrating one or more steps (e.g., acts or tasks) of FIG. 12 according to one or more embodiments of FIGS. 33 and 34; and

FIGS. 40 and 41 are plan views illustrating a display area and a color conversion layer of part B of FIG. 1 according to one or more embodiments.

### DETAILED DESCRIPTION

The subject matter of the present disclosure will be described more fully hereinafter with reference to the accompanying drawings. The subject matter of the present disclosure may, however, be embodied in different forms and should not be construed as being limited to one or more embodiments set forth herein.

The same reference numbers may refer to substantially the same components throughout the present disclosure. In the accompanying drawings, the thickness of layers and regions may be exaggerated for clarity.

One or more of the parts which are not associated with the description may not be provided in order to describe embodiments of the present disclosure.

It will also be understood that if (e.g., when) a layer is referred to as being “on” another layer or substrate, it may be directly on the other layer or substrate, or intervening layers may also be present. In contrast, if (e.g., when) an element is referred to as being “directly on” another element, there may be no intervening elements present.

Further, the phrase “in a plan view” refers to when an object portion is viewed from above, and the phrase “in a schematic cross-sectional view” refers to when a schematic cross-section taken by vertically cutting an object portion is viewed from the side. The terms “overlap” or “overlapped” refer to that a first object may be above or below or to a side of a second object, and vice versa. Additionally, the term “overlap” may include layer, stack, face, or being opposite to (e.g., facing), extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face,” “facing,” “opposite to” may refer to that a first object may directly or indirectly oppose a second object. If (e.g., when) a third object intervenes between a first object and a second object, the first object and the second object may be understood as being indirectly opposed to one another, although still opposite to (e.g., facing) each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, if (e.g., when) a device illustrated in the drawing is turned over, the device positioned or arranged “below” or “beneath” another device may be placed “above” another device. Accordingly, the illustrative term “below” may include both (e.g., simultaneously) the lower and upper positions. The device may also be oriented in other directions and thus the spatially relative terms may be interpreted differently depending on the orientations.

If (e.g., when) an element is referred to as being “connected” or “coupled” to another element, the element may be “directly connected” or “directly coupled” to another element, or “electrically connected” or “electrically coupled” to another element with one or more intervening elements therebetween. It will be further understood that if (e.g., when) the terms “includes,” “including,” “has,” “have,” and/or “having” are used, they may specify the presence of stated features, integers, steps (e.g., acts or tasks), operations, elements, and/or components, but do not preclude the presence or addition of other features, integers, steps (e.g., acts or tasks), operations, elements, components, and/or any suitable combination thereof.

It will be understood that, although the terms “first,” “second,” “third,” and/or the like may be used herein to describe one or more suitable elements, these elements should not be limited by these terms. These terms are used to distinguish one element from another element or for the convenience of description and explanation thereof. For example, if (e.g., when) “a first element” is discussed in the description, it may be termed “a second element” or “a third element,” and “a second element” and “a third element” may be termed in a similar manner without departing from the scope of the present disclosure.

The terms “about” or “approximately” as used herein is inclusive of the stated value and refers to being within an acceptable range of deviation for the particular value as determined by one of ordinary skill in the art, considering the measurement in question and the error associated with measurement of the particular quantity (for example, the limitations of the measurement system). For example, “about” may refer to being within one or more standard deviations, or within ±30%, ±20%, ±10%, or ±5% of the stated value.

In one or more embodiments, the term “and/or” is intended to include any combination of the terms “and” and “or” for the purpose of its meaning and interpretation. For example, “A and/or B” may be understood to refer to “A,” “B,” or “A and B.” The terms “and” and “or” may be used in the conjunctive or disjunctive sense and may be understood to be equivalent to “and/or.” In one or more embodiments, the phrase “at least one of” is intended to include the meaning of “at least one selected from the group of” or “at least one selected from among” for the purpose of its meaning and interpretation. For example, “at least one of A and B” or “at least one selected from among A and B” may be understood to refer to “A,” “B,” or “A and B.”

Unless otherwise defined or implied, all terms used herein (including technical and scientific terms) have substantially the same meaning as understood by those skilled in the art to which this disclosure pertains. It will be further understood that terms, such as those defined in dictionaries that are generally available or generally used, should be interpreted as having a meaning that is consistent with their meaning in the context of the relevant art and will not be interpreted in an ideal or excessively formal sense unless clearly defined in the specification.

Hereinafter, the subject matter of the present disclosure will be described in more detail with reference to the accompanying drawings.

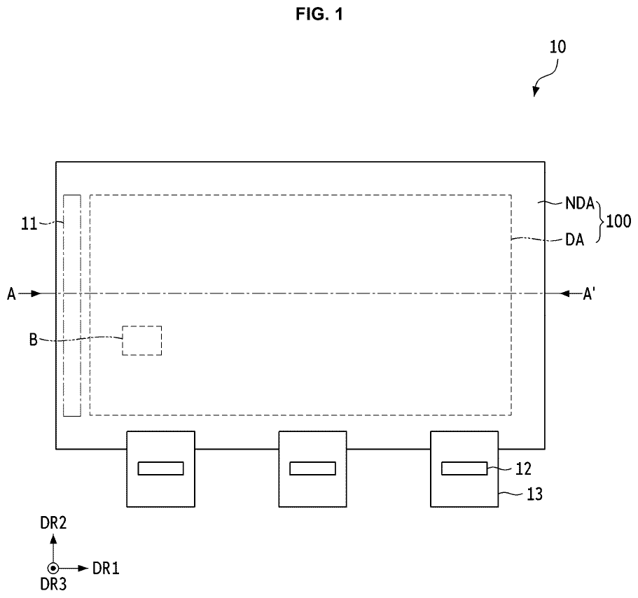

FIG. 1 is a plan view illustrating a display device according to one or more embodiments.

Referring to FIG. 1, a display device 10 according to one or more embodiments, which is a device to display a moving image or a still image, may be used as a display screen of one or more suitable devices, such as a television, a laptop computer, a monitor, a billboard, and an Internet-of-Things (IOT) device, as well as portable electronic devices, such as a mobile phone, a smartphone, a tablet personal computer (PC), a smart watch, a watch phone, a mobile communication terminal, an electronic notebook, an electronic book, a portable multimedia player (PMP), a navigation device, and/or an ultra-mobile PC (UMPC).

The display device 10 may be a light emitting display device, such as an organic light emitting display that uses an organic light emitting diode, a quantum dot light emitting display that includes a quantum dot light emitting layer, an inorganic light emitting display that includes an inorganic semiconductor, and a micro light emitting display that uses a micro or nano light emitting diode (LED). In one or more embodiments, the display device 10 may be an organic light emitting display device. However, embodiments of the present disclosure are not limited thereto and may be applied to a display device that includes an organic insulating (e.g., electrically insulating) material, an organic light emitting material, and/or a metal material.

The display device 10 may be flat (e.g., substantially flat), but embodiments of the present disclosure are not limited thereto. For example, the display device 10 may include a curved portion at left end and/or right end, and the curved portion may have a constant curvature or a varying (e.g., not constant) curvature. In one or more embodiments, the display device 10 may be flexibly so that it may be curved, bent, folded, and/or rolled.

According to one or more embodiments, the display device 10 may be an organic light emitting display device.

As illustrated in FIG. 1, the display device 10 according to one or more embodiments may include one surface of a quadrangle (e.g., a square or a rectangle). However, this is merely an example, and the shape of the display device 10 is not limited to that shown in FIG. 1. For example, the display device 10 according to one or more embodiments may include one surface of a circle or a polygon other than a quadrangle. In one or more embodiments, at least a part of the display device 10 may be unfolded, and transformed to be bent, curved, folded, and/or rolled.

One surface of the display device 10 may include a display area DA that is to light to display an image and a non-display area NDA around (e.g., surrounding) the periphery of the display area DA.

The display area DA may be in most of one surface of the display device 10.

The non-display area NDA may not emit light to display an image, and may have a frame shape that is around (e.g., surrounds) the periphery of the display area DA. For example, the non-display area NDA may be maintained in a set or predetermined color, such as black and/or the like.

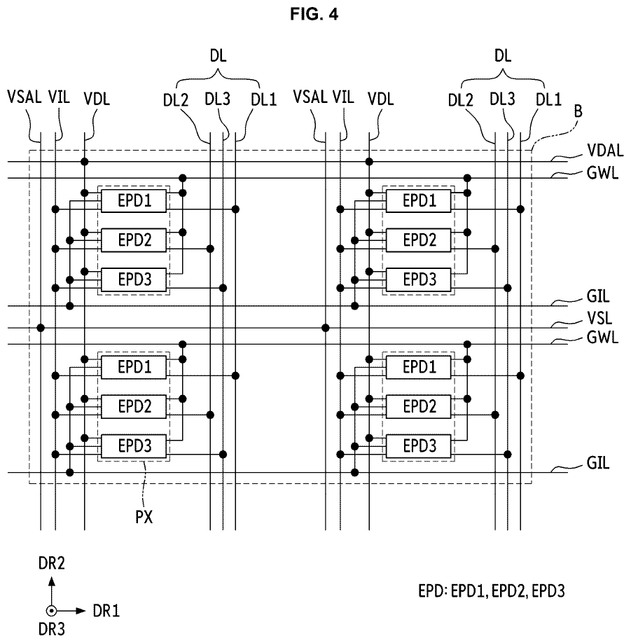

The display device 10 may include drivers 11 and 12 that are to transmit signals, voltages, or powers to light emitting pixel drivers EPD (see FIG. 4) in the display area DA.

The driver 11, which is a part of the drivers 11 and 12, may be implemented as a relatively simple circuit and may be in the non-display area NDA.

The driver 12, which is the other part of the drivers 11 and 12, may be provided as an integrated circuit chip and may be mounted on a circuit board 13 that is electrically connected to pads of the non-display area NDA. In one or more embodiments, the other driver 12 may be mounted on the pads of the non-display area NDA.

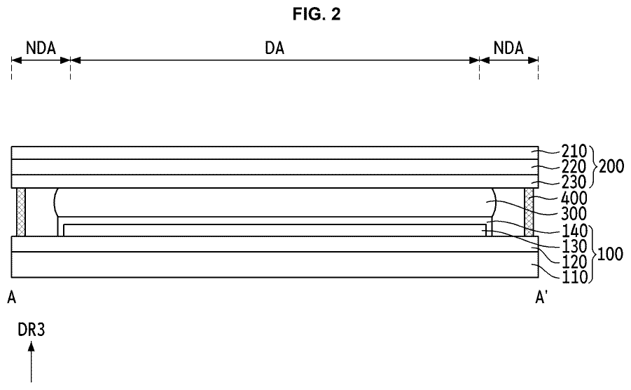

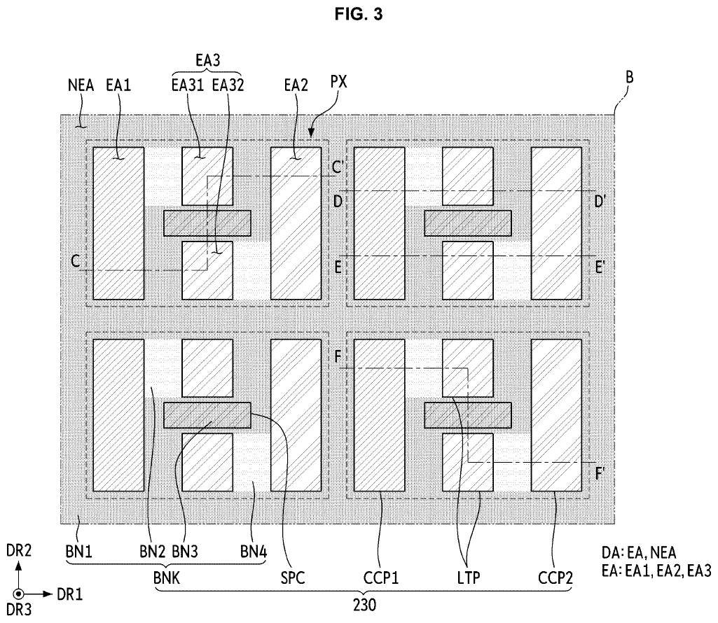

FIG. 2 is a cross-sectional view taken along the line A-A′ of FIG. 1. FIG. 3 is a layout diagram illustrating a display area and a color conversion layer of part B of FIG. 1 according to one or more embodiments.

Referring to FIG. 2, the display device 10 according to one or more embodiments may include a first substrate 100, a second substrate 200 that is opposite to (e.g., facing) the first substrate 100, and a filling layer 300 between the first substrate 100 and the second substrate 200.

The display device 10 may further include a sealing layer 400 that is in the non-display area NDA and that bonds the first substrate 100 and the second substrate 200.

Referring to FIG. 3, the display area DA may include emission areas EA that are to emit light and a non-emission area NEA between the emission areas EA.

According to one or more embodiments, the emission areas EA may include a first emission area EA1 that is to emit light in a first wavelength band, a second emission area EA2 that is to emit light in a second wavelength band, wherein the second wavelength band may be lower than the first wavelength band, and a third emission area EA3 that is to emit light in a third wavelength band, wherein the third wavelength band may be lower than the second wavelength band.

For example, the first wavelength band may be about 600 nm to about 750 nm, and the light in the first wavelength band may be red. The second wavelength band may be about 480 nm to about 560 nm, and light in the second wavelength band may be green. The third wavelength band may be about 370 nm to about 460 nm, and light in the third wavelength band may be blue.

In one or more embodiments, a unit pixel PX that is to display white light may be provided by one or more first emission areas EA1, one or more second emission areas EA2, and one or more third emission areas EA3 that are adjacent to each other among the emission areas EA.

According to one or more embodiments, the first emission area EA1, the second emission area EA2, and the third emission area EA3 may be provided side by side in a second direction DR2.

Further, according to one or more embodiments, the third emission area EA3 may be between the first emission area EA1 and the second emission area EA2 in a first direction DR1.

For example, in the first direction DR1 in which the first emission area EA1 and the third emission area EA3 are opposite to (e.g., face) each other, the third emission area EA3 may be between the first emission area EA1 and the second emission area EA2.

According to one or more embodiments, in the second direction DR2 that crosses (e.g., intersects) the first direction DR1 in which the first emission area EA1 and the third emission area EA3 are opposite to (e.g., face) each other, the third emission area EA3 may include a first divided area EA31 on one side and a second divided area EA32 on the other side.

Each of the emission areas EA may be in one shape selected from among a rectangle (e.g., a substantially rectangle), a triangle (e.g., a substantially triangle), a rhombus (e.g., a substantially rhombus), a square (e.g., a substantially square), a trapezoid (e.g., a substantially trapezoid), a circle (e.g., a substantially circle), and an ellipse (e.g., a substantially ellipse).

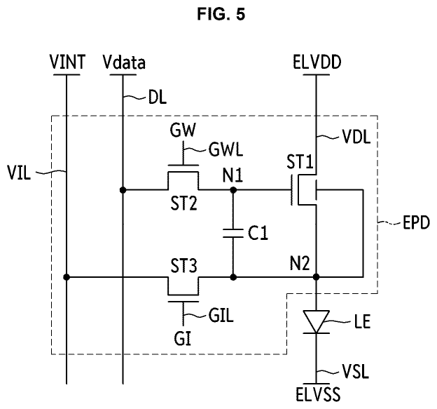

As illustrated in FIG. 2, the first substrate 100 of the display device 10 according to one or more embodiments may include a first support substrate 110 and light emitting elements LE (see FIG. 5) that are in the emission areas EA on the first support substrate 110 and that are to emit light.

According to one or more embodiments, the first substrate 100 may include the first support substrate 110, a circuit layer 120 on the first support substrate 110, an element layer 130 on the circuit layer 120, and an encapsulation layer 140 on the element layer 130.

The first support substrate 110 may include the display area DA and the non-display area NDA.

The circuit layer 120 may include the light emitting pixel drivers EPD (see FIG. 4) that are electrically connected to the light emitting elements LE, respectively.

The element layer 130 may include the light emitting elements LE respectively in the emission areas EA.

According to one or more embodiments, the light emitting elements LE may be to emit light of the fourth wavelength band, wherein the fourth wavelength band may be lower than or equal to the third wavelength band.

The encapsulation layer 140 may include two or more inorganic insulating (e.g., electrically (electron) insulating) layers including an inorganic insulating (e.g., electrically insulating) material and at least one organic insulating (e.g., electrically insulating) layer therebetween, wherein the at least one organic insulating (e.g., electrically insulating) layer may include an organic insulating (e.g., electrically insulating) material.

Due to the encapsulation layer 140, the circuit layer 120 or the element layer 130 may be prevented or protected from being damaged by foreign substances (or a degree or occurrence of being damaged by foreign substance may be reduced), and oxygen and/or moisture may be prevented from permeating (or a degree or occurrence of permeation of oxygen and/or moisture may be reduced) into the circuit layer 120 or the element layer 130.

The second substrate 200 may include a second support substrate 210 that is opposite to (e.g., faces) the first support substrate 110, a color filter layer 220 on one surface of the second support substrate 210, and a color conversion layer 230 on the color filter layer 220.

The color conversion layer 230 may be to convert at least a part of light of each of the emission areas EA emitted from the first substrate 100 into a light of another wavelength band.

The color filter layer 220 may be to selectively transmit light of one or more wavelength bands in at least one or more of the emission areas EA.

As illustrated in FIG. 3, the color conversion layer 230 according to one or more embodiments may include a bank portion BNK in the non-emission area NEA.

The bank portion BNK may include a first bank BN1 having (with) a first thickness and a second bank BN2 having (with) a second thickness that is less than the first thickness.

The second bank BN2 may be in at least a part of the non-emission area NEA between the first emission area EA1 and the third emission area EA3.

According to one or more embodiments, the bank portion BNK may further include a third bank BN3 having the second thickness in at least a part of the non-emission area NEA between the second emission area EA2 and the third emission area EA3.

According to one or more embodiments, the bank portion BNK may further include a fourth bank BN4 having the first thickness in the non-emission area NEA between the first divided area EA31 and the second divided area EA32.

According to one or more embodiments, the color conversion layer 230 may include a first color conversion portion CCP1 in the first emission area EA1, a second color conversion portion CCP2 in the second emission area EA2, and a light transmitting portion LTP in the third emission area EA3.

The first color conversion portion CCP1 may be to convert the light of the fourth wavelength band emitted from the light emitting element LE into light of the first wavelength band.

The second color conversion portion CCP2 may be to convert the light of the fourth wavelength band emitted from the light emitting element LE into light of the second wavelength band.

The light transmitting portion LTP may be to directly transmit or scatter light of the fourth wavelength band emitted from the light emitting element LE.

According to one or more embodiments, the color conversion layer 230 may further include a spacer SPC to secure a gap greater than a threshold between the first substrate 100 and the second substrate 200.

According to one or more embodiments, the spacer SPC may extend in the first direction DR1 in which the first emission area EA1 and the third emission area EA3 are opposite to (e.g., face) each other and may cross (e.g., intersect) the third emission area EA3.

For example, the spacer SPC may be between the first divided area EA31 and the second divided area EA32. In one or more embodiments, the first divided area EA31 may be adjacent to one side of the spacer SPC, and the second divided area EA32 may be adjacent to the other side of the spacer SPC.

According to one or more embodiments, the spacer SPC may overlap the fourth bank BN4.

FIG. 4 is a block diagram illustrating a circuit layer of part B of FIG. 1 according to one or more embodiments. FIG. 5 is an equivalent circuit diagram illustrating the light emitting pixel driver of FIG. 4.

Referring to FIG. 4, the circuit layer 120 of the first substrate 100 of the display device 10 according to one or more embodiments may include the light emitting pixel drivers EPD that are respectively electrically connected to the light emitting elements LE of the emission areas EA.

The light emitting pixel drivers EPD may include a first light emitting pixel driver EPD1 that is electrically connected to the light emitting element LE of the first emission area EA1, a second light emitting pixel driver EPD2 that is electrically connected to the light emitting element LE of the second emission area EA2, and a third light emitting pixel driver EPD3 that is electrically connected to the light emitting element LE of the third emission area EA3.

The circuit layer 120 may further include a scan write line GWL that is to transmit a scan write signal GW (see FIG. 5) to the light emitting pixel drivers EPD, a scan initialization line GIL that is to transmit a scan initialization signal GI (see FIG. 5) to the light emitting pixel drivers EPD, a data line DL that is to transmit a data signal Vdata (see FIG. 5) to the light emitting pixel drivers EPD, an initialization voltage line VIL that is to transmit an initialization voltage VINT (see FIG. 5) to the light emitting pixel drivers EPD, a first power line VDL that is to transmit a first power source ELVDD (see FIG. 5) to the light emitting pixel drivers EPD, and a second power line VSL that is to transmit a second power source ELVSS (see FIG. 5) to the light emitting elements LE (see FIG. 5).

The circuit layer 120 may further include a first power additional line VDAL to reduce the resistance of the first power line VDL and a second power additional line VSAL to reduce the resistance of the second power line VSL.

The first power additional line VDAL may extend in a direction that crosses (e.g., intersects) the first power line VDL and may be electrically connected to the first power line VDL.

The second power additional line VSAL may extend in a direction that crosses (e.g., intersects) the second power line VSL and may be electrically connected to the second power line VSL.

The data lines DL may include a first data line DL1 that is to transmit the data signal Vdata (see FIG. 5) of the first light emitting pixel driver EPD1, a second data line DL2 that is to transmit the data signal Vdata (see FIG. 5) of the second light emitting pixel driver EPD2, and a third data line DL3 that is to transmit the data signal Vdata (see FIG. 5) of the third light emitting pixel driver EPD3.

Referring to FIG. 5, the light emitting pixel driver EPD may be electrically connected between the first power source ELVDD and the light emitting element LE, and the light emitting element LE may be electrically connected between the light emitting pixel driver EPD and the second power source ELVSS.

The light emitting element LE may be an organic light emitting diode (OLED) having an organic light emitting layer, a quantum dot light emitting diode (LED) including a quantum dot light emitting layer, a micro LED, or an inorganic LED having an inorganic semiconductor.

For example, the anode electrode of the light emitting element LE may be electrically connected to the light emitting pixel driver EPD, and the cathode electrode of the light emitting element LE may be electrically connected to the second power source ELVSS having a voltage level lower than the first power source ELVDD.

The light emitting pixel driver EPD may include a first transistor ST1 that is to generate a driving current of the light emitting element LE and one or more capacitors C1 and one or more transistors ST2 and ST3 that are electrically connected to the first transistor ST1.

The first transistor ST1 may be electrically connected between the first power line VDL and the light emitting element LE.

The first electrode of the first transistor ST1 may be electrically connected to the first power line VDL.

The second electrode of the first transistor ST1 may be electrically connected to a second node N2 and the anode electrode of the light emitting element LE.

The first gate electrode of the first transistor ST1 may be electrically connected to a first node N1 and the second transistor ST2.

The second gate electrode of the first transistor ST1 may be electrically connected to the second node N2.

The second transistor ST2 may be electrically connected between the data line DL and the first node N1.

The gate electrode of the second transistor ST2 may be electrically connected to the scan write line GWL. For example, the second transistor ST2 may be turned on by the scan write signal of the scan write line GWL.

If (e.g., when) the second transistor ST2 is turned on, the data signal Vdata of the data line DL may be transmitted to the first node N1.

Due to the data signal Vdata transmitted to the first node N1, a voltage difference between the gate electrode of the first transistor ST1 and the first electrode of the first transistor ST1, e.g., a gate-source voltage difference, becomes a difference voltage between the first power source ELVDD and the data signal Vdata, and thus may become greater than the threshold voltage of the first transistor ST1. In one or more embodiments, by turning on the first transistor ST1, a source-drain current of a magnitude that corresponds to the data signal Vdata may be generated between the first electrode and the second electrode of the first transistor ST1. Further, the source-drain current of the first transistor ST1 may be supplied as a driving current to the light emitting element LE.

In one or more embodiments, the driving current of the magnitude that corresponds to the data signal Vdata may be supplied to the light emitting element LE and, thus, the light emitting element LE may be to emit light with a luminance that corresponds to the data signal Vdata.

The first capacitor C1 may be electrically connected between the first node N1 and the second node N2.

The first capacitor C1 may be charged by the data signal Vdata transmitted to the first node N1 through the turned-on second transistor ST2.

Hence, the potential of the first node N1 may be maintained for a set or predetermined period of time due to the voltage charged in the first capacitor C1.

The third transistor ST3 may be electrically connected between the initialization voltage line VIL and the second node N2.

The gate electrode of the third transistor ST3 may be electrically connected to the scan initialization line GIL. For example, the third transistor ST3 may be turned on by the scan initialization signal GI of the scan initialization line GIL.

If (e.g., when) the third transistor ST3 is turned on, the potential of the second node N2, e.g., the potential of the anode electrode of the light emitting element LE, may be initialized to the initialization voltage VINT of the initialization voltage line VIL.

As illustrated in FIG. 5, according to one or more embodiments, each of the first transistor ST1, the second transistor ST2, and the third transistor ST3 may be a negative (N)-type (or kind) metal-oxide-semiconductor field-effect transistor (MOSFET). However, this is merely an example, and at least one selected from among the first transistor ST1, the second transistor ST2, and the third transistor ST3 may be a positive (P)-type (or kind) MOSFET.

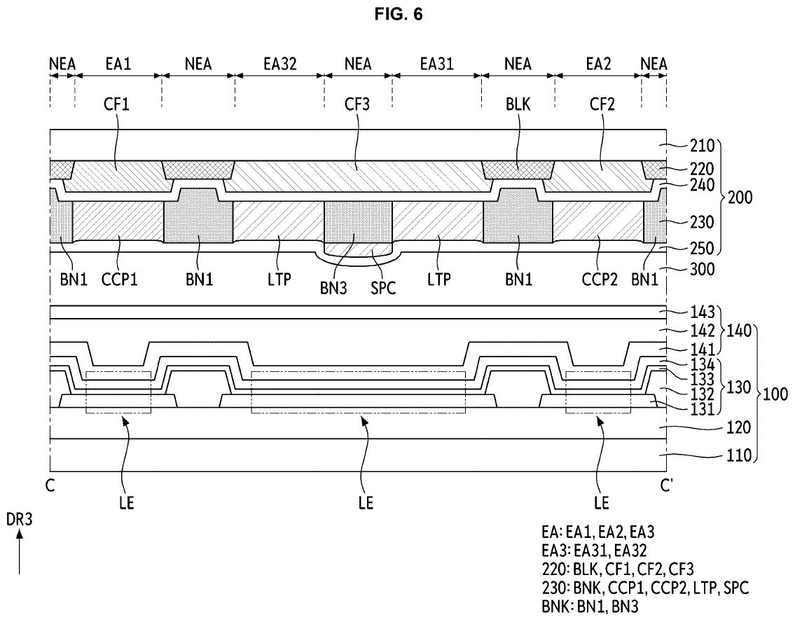

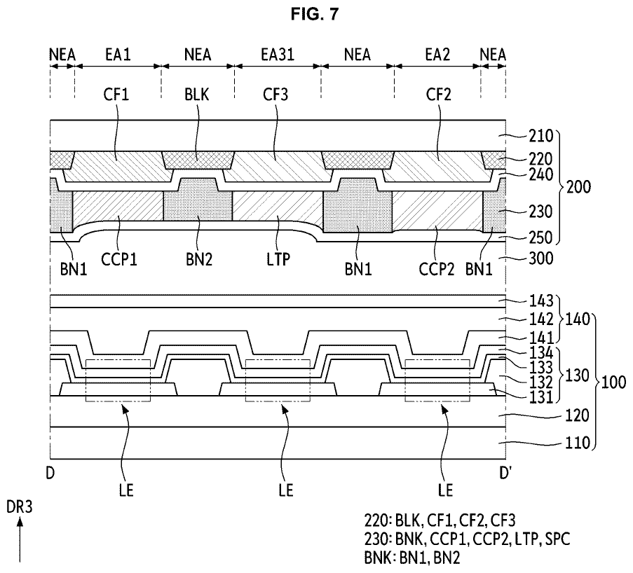

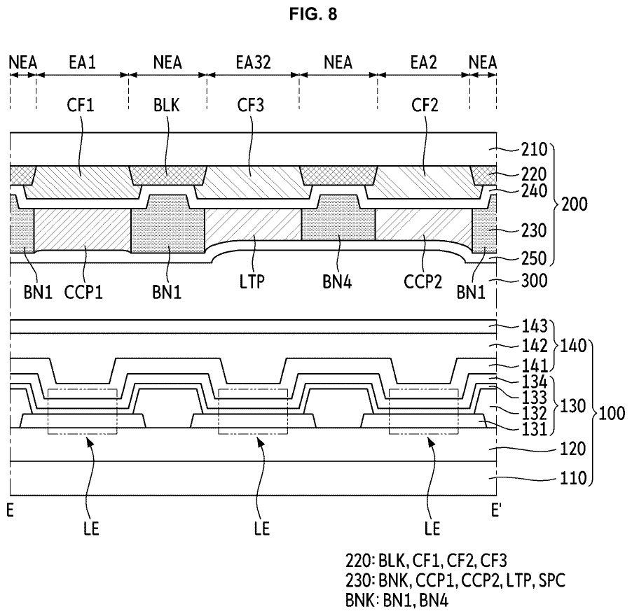

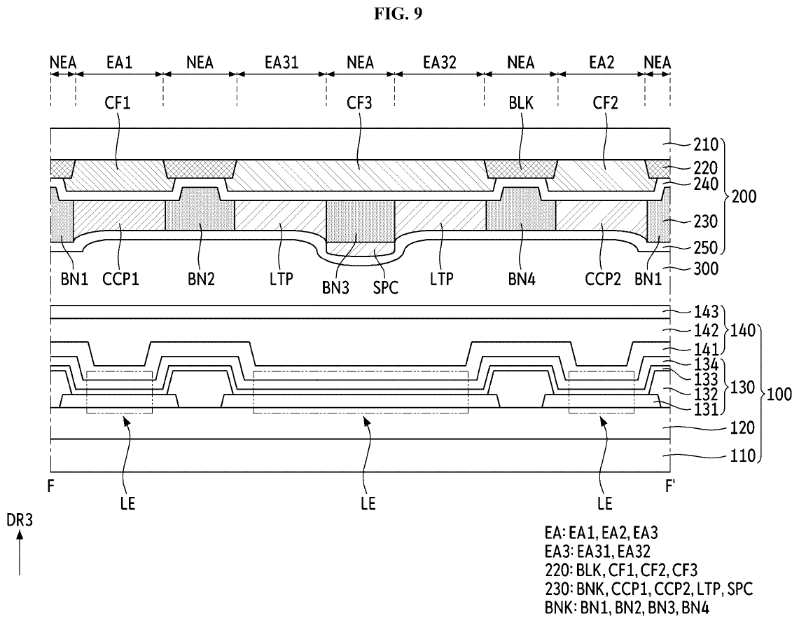

FIG. 6 is a cross-sectional view taken along the line C-C′ of FIG. 3 according to one or more embodiments. FIG. 7 is a cross-sectional view taken along the line D-D′ of FIG. 3 according to one or more embodiments. FIG. 8 is a cross-sectional view taken along the line E-E′ of FIG. 3 according to one or more embodiments. FIG. 9 is a cross-sectional view taken along the line F-F′ of FIG. 3 according to one or more embodiments.

Referring to FIGS. 6, 7, 8, and 9, the element layer 130 of the first substrate 100 of the display device 10 according to one or more embodiments may include the light emitting elements LE in the emission areas EA.

Each of the light emitting elements LE may include a structure in which a light emitting layer 133 may be between an anode electrode 131 and a cathode electrode 134 that is opposite to (e.g., faces) each other.

For example, the element layer 130 may include the anode electrodes 131 in the emission areas EA, a pixel defining layer 132 in the non-emission area NEA, wherein the pixel defining layer 132 may cover the edge of the anode electrodes 131, the light emitting layer 133 on the anode electrodes 131 and the pixel defining layer 132, and the cathode electrode 134 on the light emitting layer 133.

For example, the light emitting layer 133 may be in each of the emission areas EA.

The encapsulation layer 140 may include a first encapsulation layer 141 on the element layer 130, wherein the first encapsulation layer 141 may contain an inorganic insulating (e.g., electrically insulating) material, a second encapsulation layer 142 on the first encapsulation layer 141, wherein the second encapsulation layer 142 may contain an organic insulating (e.g., electrically insulating) material, and a third encapsulation layer 143 on the second encapsulation layer 142, wherein the third encapsulation layer 143 may contain an inorganic insulating (e.g., electrically insulating) material.

The second substrate 200 of the display device 10 according to one or more embodiments may include the second support substrate 210, the color filter layer 220 on one surface of the second support substrate 210, and the color conversion layer 230 on the color filter layer 220.

According to one or more embodiments, the second substrate 200 may further include a first capping layer 240 that covers the color filter layer 220 and a second capping layer 250 that covers the color conversion layer 230.

Each of the first capping layer 240 and the second capping layer 250 may include an inorganic insulating (e.g., electrically insulating) material.

The filling layer 300 may fill the space between the first substrate 100 and the second substrate 200.

The filling layer 300 may be between the encapsulation layer 140 of the first substrate 100 and the second capping layer 250 of the second substrate 200.

The filling layer 300 may include an organic material having a light transmitting property and an adhesive property.

For example, the filling layer 300 may include a silicon (Si)-based organic material or an epoxy-based organic material.

In a direction in which light of the light emitting elements LE of the first substrate 100 is emitted, the color conversion layer 230 may be on the filling layer 300, and the color filter layer 220 may be on the color conversion layer 230. In one or more embodiments, the light of the first substrate 100 may pass through the color conversion layer 230, the color filter layer 220, and the second support substrate 210 and be emitted to the outside.

According to one or more embodiments, the color filter layer 220 may be on one surface of the second support substrate 210 that is opposite to (e.g., faces) the first substrate 100.

The color filter layer 220 may include a light blocking portion BLK that is in the non-emission area NEA and that is to block light, a first filter portion CF1 that is in the first emission area EA1 and that is to transmit light of the first wavelength band, a second filter portion CF2 that is in the second emission area EA2 and that is to transmit light of the second wavelength band, and a third filter portion CF3 that is in the third emission area EA3 and that is to transmit light of the third wavelength band.

The light blocking portion BLK may include a material that is to absorb light, such as a black matrix material and/or the like.

In one or more embodiments, the light blocking portion BLK may include a structure in which two or more filter portions among the first filter portion CF1, the second filter portion CF2, and the third filter portion CF3 are stacked.

Each of the first filter portion CF1, the second filter portion CF2, and the third filter portion CF3 may include a colorant, such as a dye and/or a pigment. The colorant may be a material that is to absorb light of the wavelength bands other than a set or predetermined wavelength band.

For example, the first filter portion CF1 may include a colorant that is to absorb light of the wavelength bands other than the first wavelength band among the light that has transmitted through the color conversion layer 230, and thus may be to transmit light of the first wavelength band.

The second filter portion CF2 may include a colorant that is to absorb light of the wavelength bands other than the second wavelength band among the light that has transmitted through the color conversion layer 230, and thus may be to transmit light of the second wavelength band.

The third filter portion CF3 may include a colorant that is to absorb light of the wavelength bands other than the third wavelength band among the light that has transmitted through the color conversion layer 230, and thus may be to transmit light of the third wavelength band.

The second substrate 200 may further include a low refractive index layer between the color filter layer 220 and the color conversion layer 230. The low refractive index layer may include an organic material having a refractive index of about 1.1 or more and about 1.4 or less.

The first capping layer 240 may be between the color filter layer 220 and the color conversion layer 230 and may cover the color filter layer 220.

The color conversion layer 230 may be on the first capping layer 240.

According to one or more embodiments, the color conversion layer 230 may include the bank portion BNK in the non-emission area NEA.

According to one or more embodiments, the color conversion layer 230 may include the first color conversion portion CCP1 in the first emission area EA1 and the light transmitting portion LTP in the third emission area EA3.

According to one or more embodiments, the color conversion layer 230 may further include the second color conversion portion CCP2 in the second emission area EA2.

The bank portion BNK may be around (e.g., surround) the periphery of each of the first color conversion portion CCP1, the second color conversion portion CCP2, and the light transmitting portion LTP.

For example, the bank portion BNK may include a light blocking material that is to block visible light. In one or more embodiments, color mixing in the color conversion layer 230 may be prevented (or a degree or occurrence of color mixing in the color conversion layer 230 may be reduced) between the adjacent emission areas EA by the bank portion BNK.

The first color conversion portion CCP1 may be a cured product of a first ink material including a base resin and first color conversion particles dispersed in the base resin. The first color conversion particles may be to convert the light of the fourth wavelength band into light of the first wavelength band.

The second color conversion portion CCP2 may be a cured product of a second ink material including a base resin and second color conversion particles dispersed in the base resin. The second color conversion particles may be to convert the light of the fourth wavelength band into light of the second wavelength band.

The light transmitting portion LTP may include a base resin and/or scattering particles dispersed in the base resin.

The scattering particles may be metal oxide particles and/or organic particles.

The metal oxide particles may be at least one of titanium oxide (TiO₂), zirconium oxide (ZrO₂), aluminum oxide (Al₂O₃), indium oxide (In₂O₃), zinc oxide (ZnO), or tin oxide (SnO₂).

The organic particles may be an acrylic resin and/or a urethane resin.

Each of the first color conversion portion CCP1 and the second color conversion portion CCP2 may further include scattering particles dispersed in the base resin.

Each of the first color conversion particle and the second color conversion particle may be at least one selected from among a quantum dot, a quantum rod, and a phosphor.

The quantum dot may be any one selected from among group IV nanocrystals, group II-VI compound nanocrystals, group III-V compound nanocrystals, group IV-VI nanocrystals, and/or one or more (e.g., any suitable) combinations thereof.

The first color conversion portion CCP1, the second color conversion portion CCP2, and the light transmitting portion LTP may include substantially the same base resin or may include different base resins.

As illustrated in FIG. 3, according to one or more embodiments, the emission areas EA may include the first emission area EA1, the second emission area EA2, and the third emission area EA3.

According to one or more embodiments, in the first direction DR1 in which the first emission area EA1 and the third emission area EA3 are opposite to (e.g., face) each other, the third emission area EA3 may include the first divided area EA31 on one side and the second divided area EA32 on the other side.

As illustrated in FIGS. 3, 7, 8, and 9, according to one or more embodiments, the color conversion layer 230 may include the bank portion BNK in the non-emission area NEA, the first color conversion portion CCP1 in the first emission area EA1, and the light transmitting portion LTP in the third emission area EA3.

The bank portion BNK may include the first bank BN1 having (with) the first thickness and the second bank BN2 having (with) the second thickness that is less than the first thickness.

The second bank BN2 may be in the non-emission area NEA between the first emission area EA1 and the first divided area EA31.

Each of the first color conversion portion CCP1 and the light transmitting portion LTP may be surrounded by the bank portion BNK.

The light transmitting portion LTP may be in the bank portion BNK.

In one or more embodiments, as illustrated in FIGS. 7 and 9, a part of the light transmitting portion LTP between the first bank BN1 and the second bank BN2 may have a thickness that varies from the first thickness to the second thickness (e.g., a thickness between the first thickness and the second thickness). In one or more embodiments, a part of the light transmitting portion LTP that is in the first divided area EA31 may have an inclined top surface.

As illustrated in FIG. 6, a part of the light transmitting portion LTP that is surrounded by the first bank BN1 may have the first thickness.

A part of the first color conversion portion CCP1 between the first bank BN1 and the second bank BN2 may also have a thickness that varies from the first thickness to the second thickness (e.g., a thickness between the first thickness and the second thickness). However, this is merely an example, and the shape of the first color conversion portion CCP1 may not be dependent on the bank portion BNK depending on the drop amount of the first ink material and the curing environment of the first ink material during the arrangement process of the first color conversion portion CCP1.

As illustrated in FIGS. 3, 6 and 9, according to one or more embodiments, the color conversion layer 230 may include the spacer SPC that extends in the first direction DR1 in which the first emission area EA1 and the third emission area EA3 are opposite to (e.g., face) each other and that crosses (e.g., intersects) the third emission area EA3.

The bank portion BNK may further include the third bank BN3 between the first divided area EA31 and the second divided area EA32.

The spacer SPC may be on the first bank BN1 and the third bank BN3.

The spacer SPC may be together with the light transmitting portion LTP. For example, the spacer SPC may include substantially the same material as the light transmitting portion LTP.

As illustrated in FIGS. 3, 8 and 9, according to one or more embodiments, the bank portion BNK may further include the fourth bank BN4 having the second thickness between the second emission area EA2 and the second divided area EA32.

In one or more embodiments, another part of the light transmitting portion LTP between the first bank BN1 and the fourth bank BN4 may have a thickness that varies from the first thickness to the second thickness (e.g., a thickness between the first thickness and the second thickness).

A part of the second color conversion portion CCP2 between the first bank BN1 and the fourth bank BN4 may also have a thickness that varies from the first thickness to the second thickness (e.g., a thickness between the first thickness and the second thickness). However, this is merely an example, and the shape of the second color conversion portion CCP2 may not be dependent on the bank portion BNK depending on the drop amount of the second ink material and the curing environment of the second ink material during the arrangement process of the second color conversion portion CCP2.

According to one or more embodiments, each of the bank portion BNK and the light transmitting portion LTP may have a hydrophobic surface (e.g., a surface having a water-repelling property and/or a water-resistant property).

In one or more embodiments, due to the hydrophobic property (e.g., a water-repelling property and/or a water-resistant property) of each of the bank portion BNK and the light transmitting portion LTP and the partially inclined top surface of the light transmitting portion LTP that is in the first divided area EA31, the first ink material dropped on a part of the light transmitting portion LTP and the second bank BN2 may relatively easily flow to the first emission area EA1.

According to one or more embodiments, the width of the first emission area may become less than the width of the area where the first ink material to provide the first color conversion portion CCP1 is dropped. For example, the width of the first emission area may become less than the minimum margin of the ink ejection process. In one or more embodiments, the minimum margin of the ink ejection process may not affect the width of the emission area, which may be advantageous or beneficial for realizing or providing relatively high resolution of the display device.

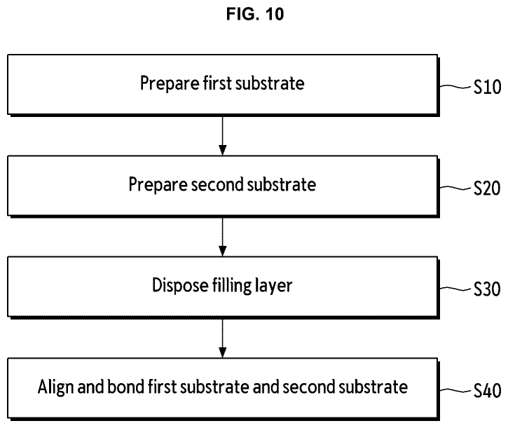

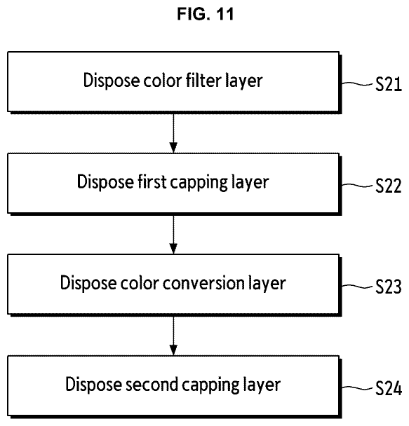

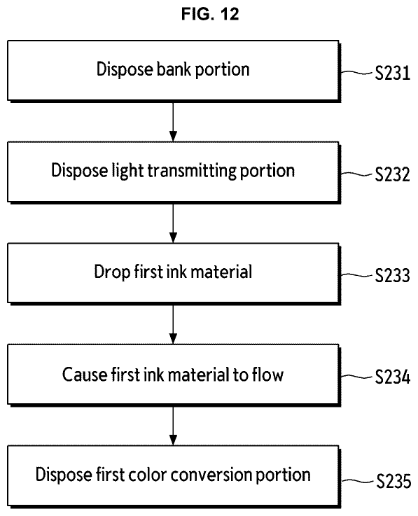

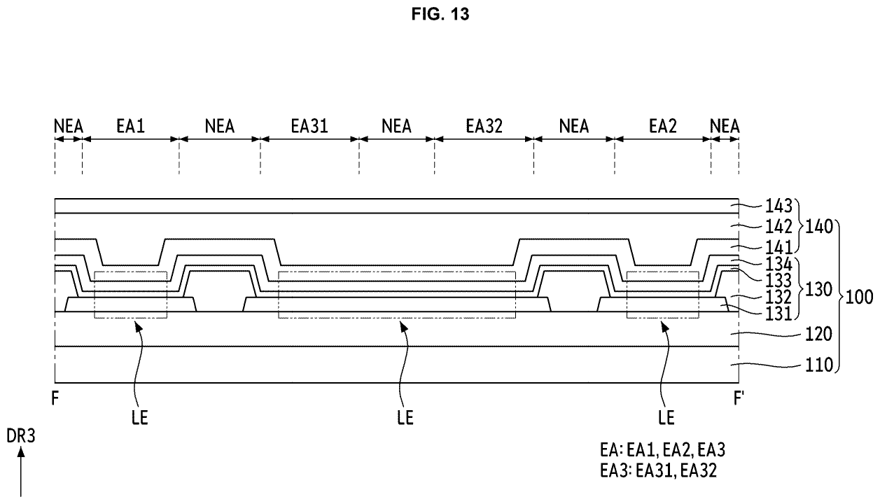

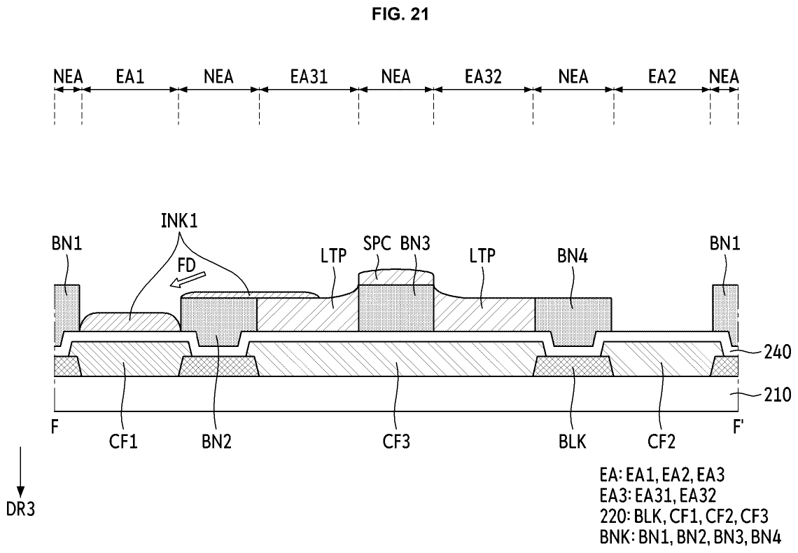

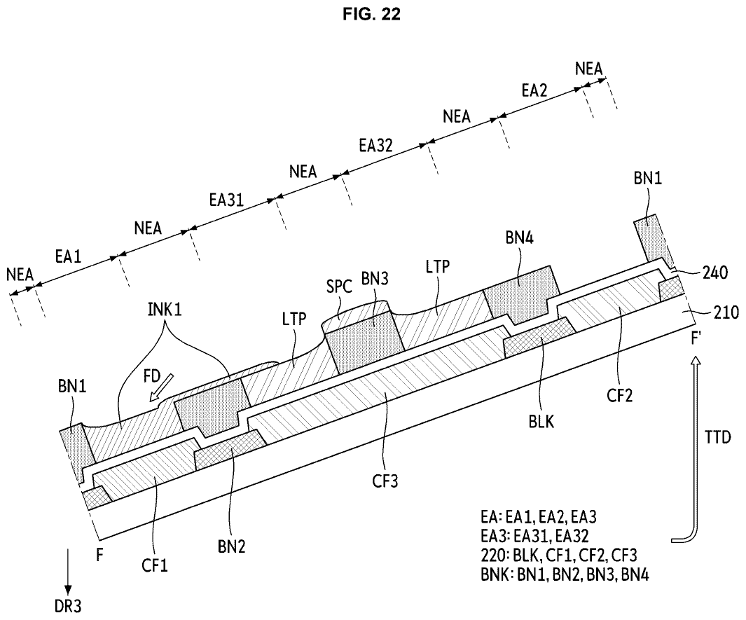

FIG. 10 is a flowchart illustrating a method for manufacturing the display device according to one or more embodiments. FIG. 11 is a flowchart illustrating steps (e.g., acts or tasks) of preparing the second substrate of FIG. 10. FIG. 12 is a flowchart illustrating steps (e.g., acts or tasks) of providing the color conversion layer of FIG. 11. FIGS. 13, 14, 15, 16, 17, 18, 19, 20, 21, 22, 23, 24, 25, 26, 27, 28 and 29 are process views illustrating one or more steps (e.g., acts or tasks) of FIGS. 10, 11 and 12 according to one or more embodiments of FIG. 9.

Referring to FIG. 10, a method for manufacturing the display device 10 according to one or more embodiments may include preparing the first substrate 100 including the light emitting elements LE in the emission areas EA (step (e.g., act or task) S10), preparing the second substrate 200 including the color filter layer 220 and the color conversion layer 230 (step (e.g., act or task) S20), providing the filling layer 300 on the first substrate 100 or the second substrate 200 (step (e.g., act or task) S30), and aligning the first substrate 100 and the second substrate 200 to be opposite to (e.g., face) each other and bonding the first substrate 100 and the second substrate 200 to each other (step (e.g., act or task) S40).

Referring to FIG. 11, step (e.g., act or task) S20 of preparing the second substrate 200 may include providing the color filter layer 220 on the second support substrate 210 (step (e.g., act or task) S21), providing the first capping layer 240 that covers the color filter layer 220 (step (e.g., act or task) S22), providing the color conversion layer 230 on the first capping layer 240 (step (e.g., act or task) S23), and providing the second capping layer 250 that covers the color conversion layer 230 (step (e.g., act or task) S24).

Referring to FIG. 12, step (e.g., act or task) S23 of providing the color

conversion layer 230 may include providing the bank portion BNK in the non-emission area NEA between the emission areas EA (step (e.g., act or task) S231).

In step (e.g., act or task) S231 of providing the bank portion BNK, the bank portion BNK may include the first bank BN1 having the first thickness and the second bank BN2 having the second thickness that is less than the first thickness.

Further, step (e.g., act or task) S23 of providing the color conversion layer 230 may further include providing the light transmitting portion LTP that is to transmit light of the fourth wavelength band emitted from the light emitting element LE in the third emission area EA3 (step (e.g., act or task) S232) and providing the first color conversion portion CCP1 that is to convert the light of the fourth wavelength band emitted from the light emitting element LE into light of the first wavelength band in the first emission area EA1 (steps (e.g., acts or tasks) S233, S234, and S235).

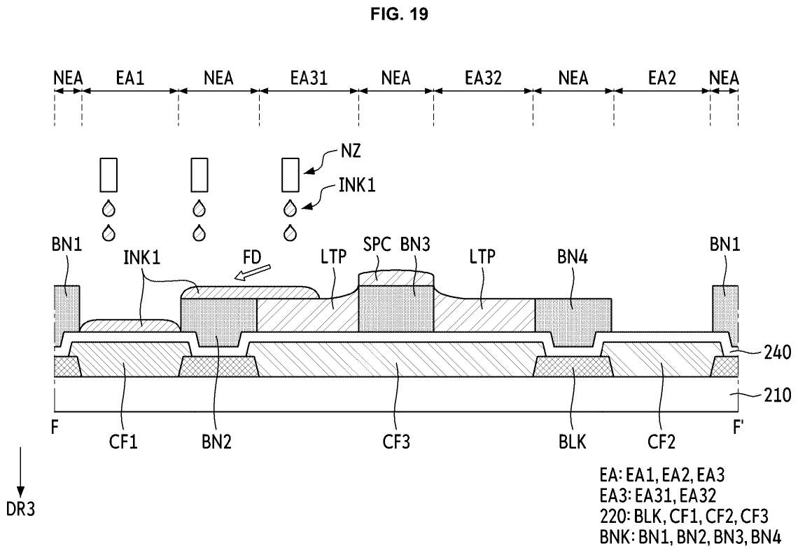

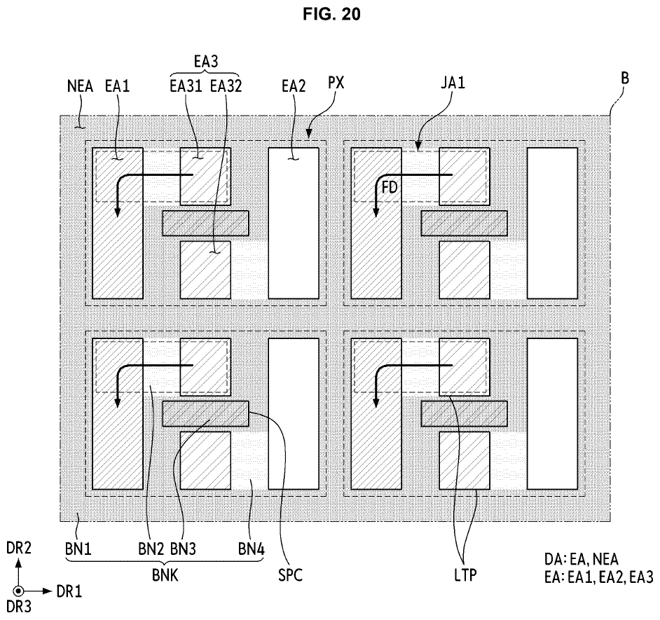

Steps (e.g., acts or tasks) S233, S234, and S235 of providing the first color conversion portion CCP1 may include dropping a first ink material INK1 (see FIG. 19) in a first drop area JA1 (see FIG. 20) including a part of the first emission area EA1 that is adjacent to one side of the second bank BN2, the first divided area EA31, and the second bank BN2 (step (e.g., act or task) S233), causing a part of the first ink material INK1 dropped on the second bank BN2 and the light transmitting portion LTP to flow to the first emission area EA1 due to the inclined top surface of the light transmitting portion LTP and the hydrophobic property (e.g., a water-repelling property and/or a water-resistant property) of the surface of each of the second bank BN2 and the light transmitting portion LTP (step (e.g., act or task) S234), and providing the first color conversion portion CCP1 by curing the first ink material INK1 in the first emission area EA1 (step (e.g., act or task) S235).

Referring to FIG. 13, in step (e.g., act or task) S10 of preparing the first substrate 100, the first substrate 100 may include the light emitting elements LE in the emission areas EA.

Step (e.g., act or task) S10 of preparing the first substrate 100 may include a process of preparing the first support substrate 110 including the display area DA and the non-display area NDA, a process of providing the circuit layer 120 on the first support substrate 110, a process of providing the element layer 130 on the circuit layer 120, and a process of providing the encapsulation layer 140 on the element layer 130.

The element layer 130 may include the anode electrodes 131 in the emission areas EA, the pixel defining layer 132 in the non-emission area NEA, wherein the pixel defining layer 132 may cover the edges of the anode electrodes 131, the light emitting layer 133 on the anode electrodes 131 and the pixel defining layer 132, and the cathode electrode 134 on the light emitting layer 133.

The light emitting elements LE may be in the emission areas EA and may each include a structure in which the light emitting layer 133 is between the anode electrode 131 and the cathode electrode 134 that are opposite to (e.g., face) each other.

The encapsulation layer 140 may include the first encapsulation layer 141 on the element layer 130, wherein the first encapsulation layer 141 may contain an inorganic insulating (e.g., electrically insulating) material, the second encapsulation layer 142 on the first encapsulation layer 141, wherein the second encapsulation layer 142 may contain an organic insulating (e.g., electrically insulating) material, and the third encapsulation layer 143 on the second encapsulation layer 142, wherein the third encapsulation layer 143 may contain an inorganic insulating (e.g., electrically insulating) material.

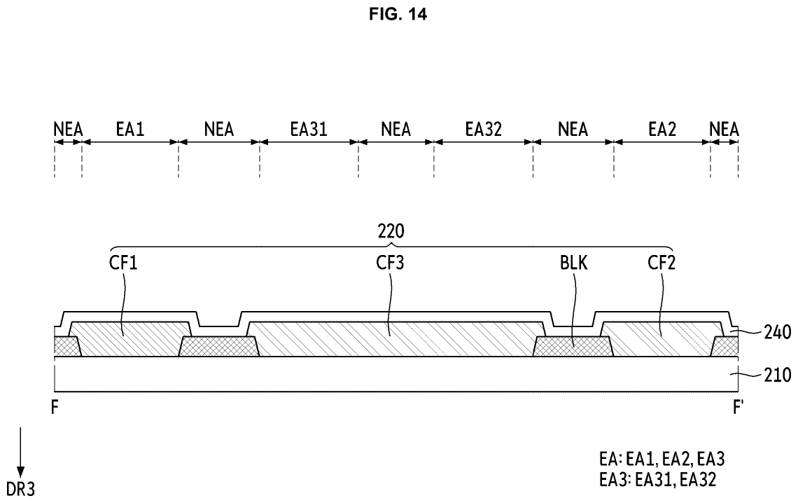

Referring to FIG. 14, in step (e.g., act or task) S21 of providing the color filter layer 220 on the second support substrate 210 in step (e.g., act or task) S20 of preparing the second substrate 200, the color filter layer 220 may include the light blocking portion BLK that is in the non-emission area NEA and that is to block light, the first filter portion CF1 that is in the first emission area EA1 and that is to transmit light of the first wavelength band, the second filter portion CF2 that is in the second emission area EA2 and that is to transmit light of the second wavelength band, and the third filter portion CF3 that is in the third emission area EA3 and that is to transmit light of the third wavelength band.

In step (e.g., act or task) S22 of providing the first capping layer 240, the first capping layer 240 may be provided by stacking an inorganic insulating (e.g., electrically insulating) material that covers the color filter layer 220.

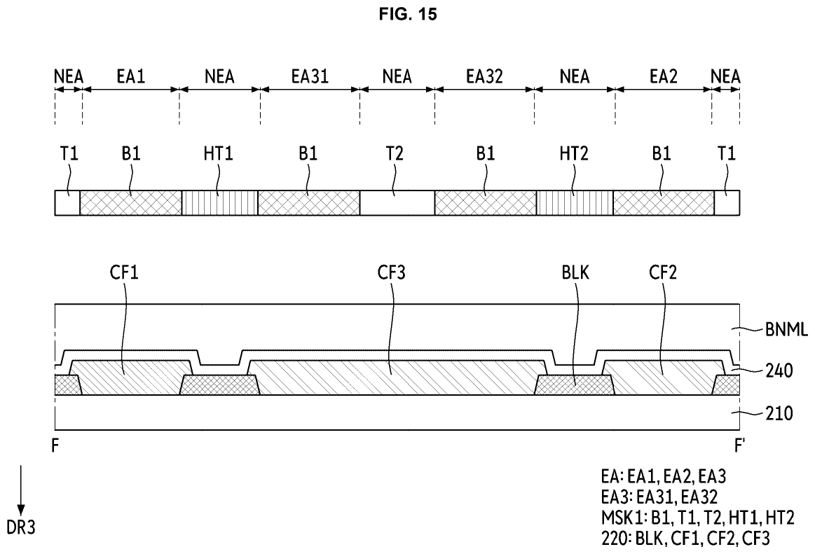

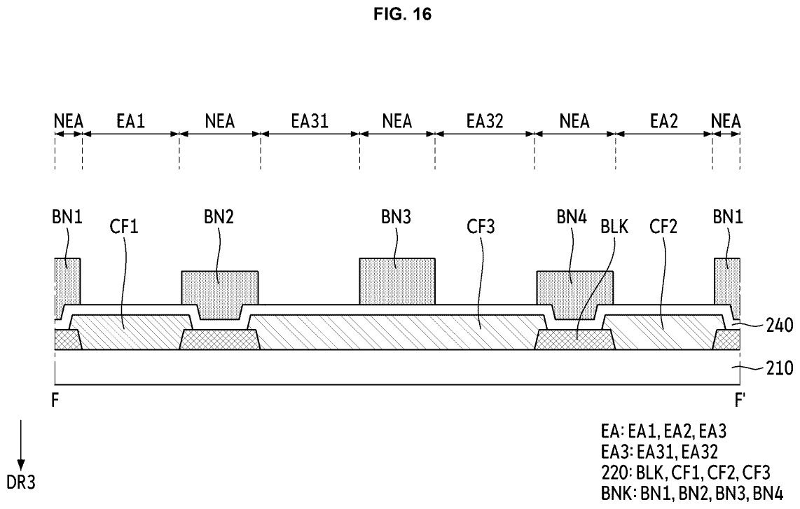

Referring to FIGS. 15 and 16, step (e.g., act or task) S231 of providing the bank portion BNK in step (e.g., act or task) S23 of providing the color conversion layer may include a step (e.g., act or task) of exposing a bank material layer BNML on the first capping layer 240 by utilizing a first mask MSK1 and a step (e.g., act or task) of developing the bank material layer BNML.

As illustrated in FIG. 15, in the step (e.g., act or task) of exposing the bank material layer BNML, the bank material layer BNML may include a negative photoresist material.

In one or more embodiments, the first mask MSK1 may include a first blocking portion B1 that is opposite to (e.g., faces) the emission areas EA, a first transmitting portion T1 that is opposite to (e.g., faces) a part of the non-emission area NEA and that is to transmit light, and a first semi-transmitting portion HT1 that is opposite to (e.g., faces) another part of the non-emission area NEA and that is to transmit a smaller amount of light than the first transmitting portion T1.

The first semi-transmitting portion HT1 may be opposite to (e.g., may face) a part of the non-emission area between the first emission area EA1 and the first divided area EA31.

As illustrated in FIG. 16, in the step (e.g., act or task) of developing the bank material layer BNML, the first bank BN1 having the first thickness may be provided by a part of the bank material layer BNML that is opposite to (e.g., faces) the transmitting portion T1 of the first mask MSK1.

Further, the second bank BN2 having the second thickness that is less than the first thickness may be provided by another part of the bank material layer BNML that is opposite to (e.g., faces) the first semi-transmitting portion HT1 of the first mask MSK1.

In contrast, the remaining part of the bank material layer BNML that is opposite to (e.g., faces) the first blocking portion B1 of the first mask MSK1 may be removed by a developer.

In one or more embodiments, the bank portion BNK including the first bank BN1 and the second bank BN2 may be provided.

In the step (e.g., act or task) of exposing the bank material layer BMNL and the step (e.g., act or task) of developing the bank material layer BMNL, the hydrophobic material (e.g., the material having a water-repelling property and/or a water-resistant property) included in the bank material layer BNML may react with light and flow to the surface. Because the bank portion BNK is provided by a part of the bank material layer BNML that is exposed to light, the bank portion BNK may have a hydrophobic surface (e.g., a surface having a water-repelling property and/or a water-resistant property).

According to one or more embodiments, as illustrated in FIG. 15, the first mask MSK1 may further include a second transmitting portion T2 that crosses (e.g., intersects) the third emission area EA3.

The second transmitting portion T2 may be opposite to (e.g., may face) a part of the non-emission area NEA between the first divided area EA31 and the second divided area EA32.

Further, the second transmitting portion T2 may extend in the first direction DR1 in which the first emission area EA1 and the third emission area EA3 are opposite to (e.g., face) each other.

In one or more embodiments, as illustrated in FIG. 16, the third bank BN3 having the first thickness may be provided by a part of the bank material layer BNML that is opposite to (e.g., faces) the second transmitting portion T2 of the first mask MSK1.

According to one or more embodiments, as illustrated in FIG. 15, the first mask MSK1 may further include a second semi-transmitting portion HT2 that is opposite to (e.g., faces) a part of the non-emission area NEA between the second emission area EA2 and the second divided area EA32.

In one or more embodiments, as illustrated in FIG. 16, the fourth bank BN4 having the second thickness may be provided by a part of the bank material layer BNML that is opposite to (e.g., faces) the second semi-transmitting portion HT2 of the first mask MSK1.

In one or more embodiments, the bank portion BNK according to one or more embodiments may include the first bank BN1 having the first thickness in a part of the non-emission area NEA, the second bank BN2 having the second thickness between the first emission area EA1 and the first divided area EA31, the third bank BN3 having the first thickness between the first divided area EA31 and the second divided area EA32, and the fourth bank BN4 having the second thickness between the second emission area EA2 and the second divided area EA32.

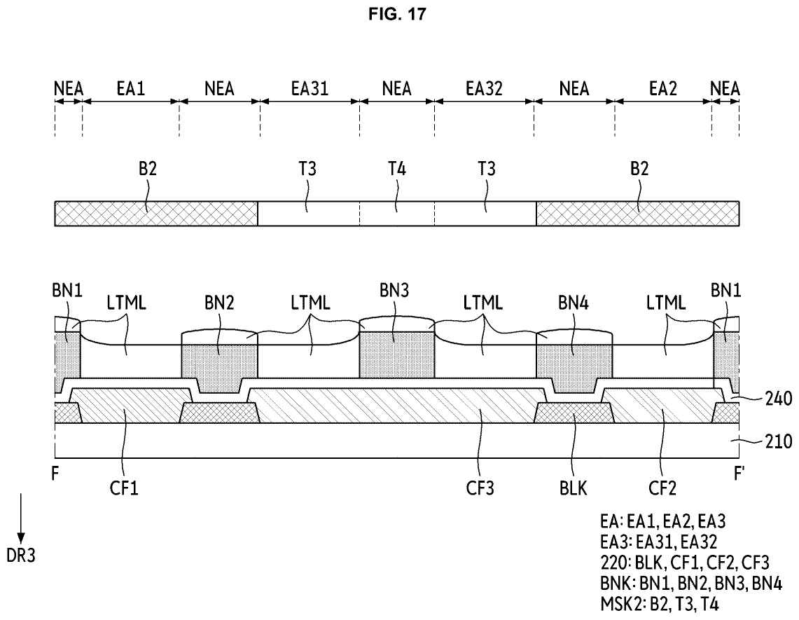

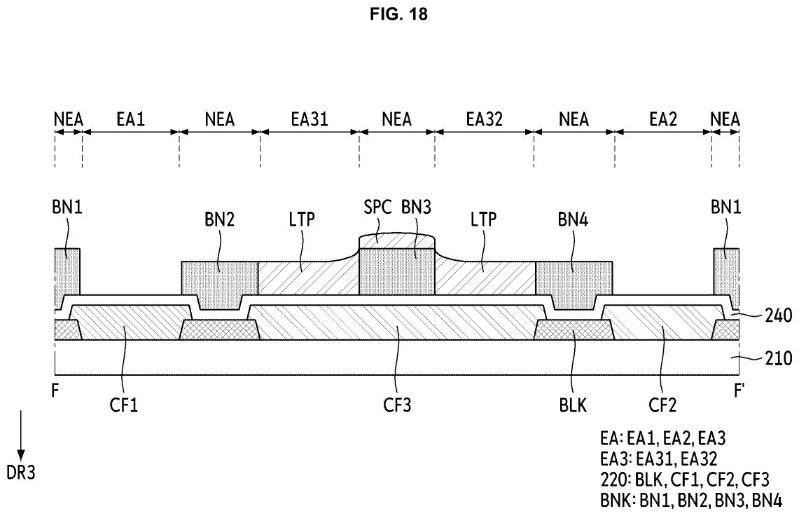

Referring to FIGS. 17 and 18, step (e.g., act or task) S232 of providing the light transmitting portion LTP may include a step (e.g., act or task) of exposing a light transmitting material layer LTML that covers the first capping layer 240 and the bank portion BNK by utilizing a second mask MSK2, and a step (e.g., act or task) of developing the light transmitting material layer LTML.

As illustrated in FIG. 17, in the step (e.g., act or task) of exposing the light transmitting material layer LTML, the light transmitting material layer LTML stacked on the first capping layer 240 may be in the area surrounded by the bank portion BNK.

Further, a part of the light transmitting material layer LTML may be on the bank portion BNK.

The light transmitting material layer BNML may include a negative photoresist material.

In one or more embodiments, the second mask MSK2 may include a second blocking portion B2 that is opposite to (e.g., faces) the first emission area EA1 and the non-emission area NEA, and a third transmitting portion T3 that is opposite to (e.g., faces) the third emission area EA3.

According to one or more embodiments, the second blocking portion B2 may also be opposite to (e.g., may face) the second emission area EA2.

According to one or more embodiments, the third emission area EA3 may include the first divided area EA31 and the second divided area EA32, and the third transmitting portion T3 may be opposite to (e.g., may face) each of the first divided area EA31 and the second divided area EA32.

Further, the second mask MSK2 may further include a fourth transmitting portion T4 that is opposite to (e.g., faces) the third bank BN3.

As illustrated in FIG. 18, in the step (e.g., act or task) of developing the light transmitting material layer LTML, the light transmitting portion LTP may be provided by a part of the light transmitting material layer LTML that is opposite to (e.g., faces) the third transmitting portion T3.

According to one or more embodiments, the spacer SPC on the third bank BN3 may be provided by another part of the light transmitting material layer LTML that is opposite to (e.g., faces) the fourth transmitting portion T4.

Further, the remaining part of the light transmitting material layer LTML that is opposite to (e.g., faces) the second blocking portion B2 of the second mask MSK2 may be removed by a developer.

In the step (e.g., act or task) of exposing the light transmitting material layer LTML and the step (e.g., act or task) of developing the light transmitting material layer LTML, a hydrophobic substance (e.g., a substance having a water-repelling property and/or a water-resistant property) included in the light transmitting material layer LTML may react with light and flow to the surface. Because the light transmitting portion LTP and the spacer SPC are provided by a part of the light transmitting material layer LTML that is exposed to light, each of the light transmitting portion LTP and the spacer SPC may have a hydrophobic surface (e.g., a surface having a water-repelling property and/or a water-resistant property).

Further, the light transmitting material layer LTML of the third emission area EA3, which is in the area surrounded by the first bank BN1 and the second bank BN2, may be exposed to light incident through the third transmitting portion T3, so that the light transmitting portion LTP may be provided. In one or more embodiments, the light transmitting portion LTP may be in a shape that substantially corresponds to the first bank BN1 and the second bank BN2. For example, a part of the light transmitting portion LTP between the first bank BN1 and the second bank BN2 may have a thickness that varies from the first thickness to the second thickness (e.g., a thickness between the first thickness and the second thickness), and thus may have an inclined top surface.

Referring to FIGS. 19, 20, 21, 22, and 23, the step (e.g., act or task) of providing the first color conversion portion CCP1 may include a step (e.g., act or task) of dropping the first ink material INK1 in the first drop area JA1, a step (e.g., act or task) of causing a part of the first ink material INK1 to flow to the first emission area EA1, and a step (e.g., act or task) of providing the first color conversion portion CCP1 by curing the first ink material INK1 in the first emission area EA1.

Referring to FIGS. 19 and 20, in the step (e.g., act or task) of dropping the first ink material INK1 in the first drop area JA1, the nozzle NZ moved onto the first drop area JA1 may eject the first ink material INK1, so that the first ink material INK1 may be dropped in the first drop area JA1.

The first drop area JA1 may include a part of the first emission area EA1 that is adjacent to one side of the second bank BN2, the first divided area EA31 of the third emission area EA3 that is adjacent to the other side of the second bank BN2, and the second bank BN2.

For example, according to one or more embodiments, the first drop area JA1 is not limited to the first emission area EA1 and may extend to the second bank BN2 and the first divided area EA31 in addition to the first emission area EA1. In one or more embodiments, the width of the first emission area EA1 may become less than the width of the first drop area JA1, which may be advantageous or beneficial for realizing or providing relatively high resolution of the display device 10.

Each of the bank portion BNK and the light transmitting portion LTP may have a hydrophobic surface (e.g., a surface having a water-repelling property and/or a water-resistant property), and the light transmitting portion LTP may have an inclined top surface between the first bank BN1 and the second bank BN2. Because the first ink material INK1 has a hydrophilic property (e.g., a high affinity for water), a part of the first ink material INK1 dropped on the light transmitting portion LTP and the second bank BN2 in the first drop area JA1 may relatively easily flow in a flow direction FD toward the first emission area EA1 due to the hydrophobic property (e.g., a water-repelling property and/or a water-resistant property) of the surface of each of the bank portion BNK and the light transmitting portion LTP and the inclined top surface of the light transmitting portion LTP.

In one or more embodiments, as illustrated in FIG. 19, a part of the first ink material INK1 dropped in an area of the first drop area JA1 other than the first emission area EA1 may flow along the flow direction FD, and thus may be in the first emission area EA1.

According to one or more embodiments, as illustrated in FIG. 20, in a step (e.g., act or task) of causing a part of the first ink material INK1 to flow, the second support substrate 210 may be tilted in a tilting direction TTD that increases the inclination of the flow direction FD.

For example, the tilting angle of the second support substrate 210 may be about 15 degrees or more.

In one or more embodiments, the fluidity of a part of the first ink material INK1 may be increased, so that a defect in which a part of the first ink material INK1 remains in an area of the first drop area JA1 other than the first emission area EA1 may be prevented (or a degree or occurrence of such defect may be reduced).

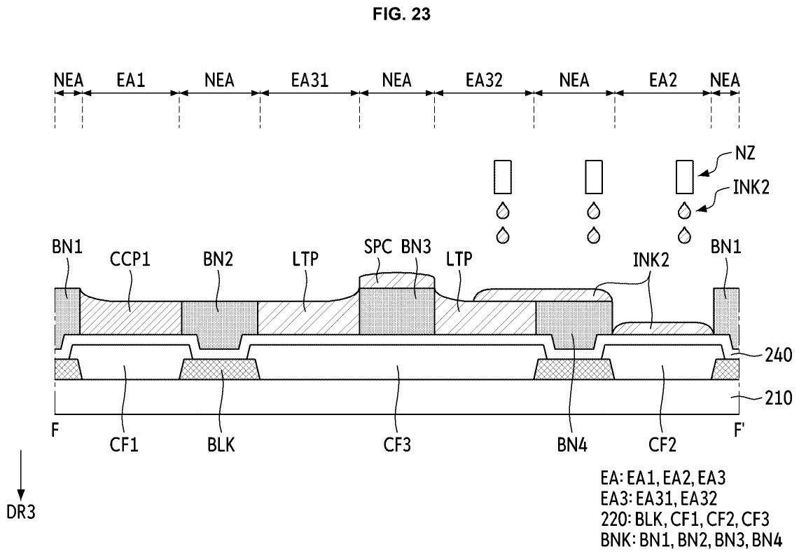

As illustrated in FIG. 23, the first color conversion portion CCP1 may be provided by curing the first ink material INK1 in the first emission area EA1.

According to one or more embodiments, step (e.g., act or task) S23 of providing the color conversion layer 230 may further include a step (e.g., act or task) of providing the second color conversion portion CCP2 that is to convert the light of the fourth wavelength band emitted from the light emitting element LE into light of the second wavelength band in the second emission area EA2.

In one or more embodiments, the bank portion BNK may further include the fourth bank BN4 having the second thickness in the non-emission area between the second emission area EA2 and the second divided area EA32.

In one or more embodiments, a part of the light transmitting portion LTP between the first bank BN1 and the fourth bank BN4 may have an inclined top surface due to the thickness that varies from the first thickness to the second thickness (e.g., the thickness between the first thickness and the second thickness).

Referring to FIGS. 23, 24, 25, 26, and 27, the step (e.g., act or task) of providing the second color conversion portion CCP2 may include a step (e.g., act or task) of dropping a second ink material INK2 in a second drop area JA2, a step (e.g., act or task) of causing a part of the second ink material INK2 to flow to the second emission area EA2, and a step (e.g., act or task) of providing the second color conversion portion CCP2 by curing the second ink material INK2 in the second emission area EA2.

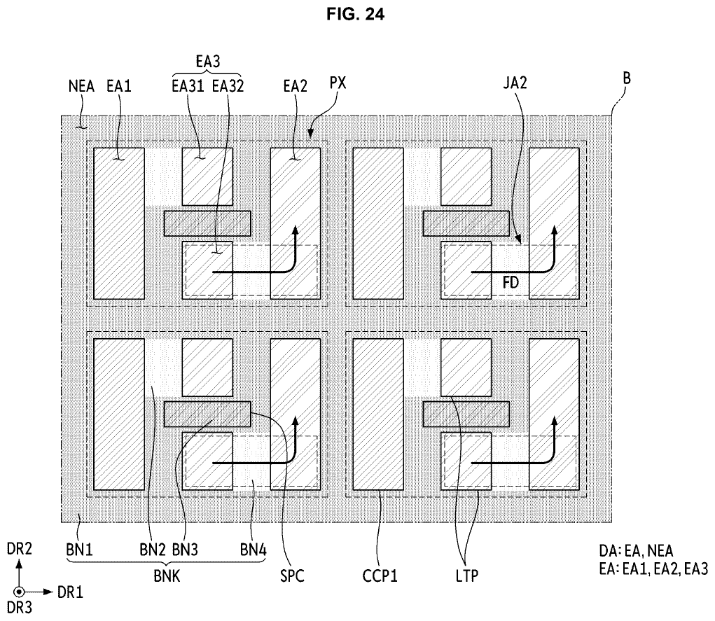

Referring to FIGS. 23 and 24, in the step (e.g., act or task) of dropping the second ink material INK2 in the second drop area JA2, the nozzle NZ moved onto the second drop area JA2 may eject the second ink material INK2, so that the second ink material INK2 may be dropped in the second drop area JA2.

The second drop area JA2 may include a part of the second emission area EA2 that is adjacent to one side of the fourth bank BN4, the second divided area EA32 of the third emission area EA3 that is adjacent to the other side of the fourth bank BN4, and the fourth bank BN4.

For example, according to one or more embodiments, the second drop area JA2 is not limited to the second emission area EA2 and may extend to the fourth bank BN4 and the second divided area EA32, in addition to the second emission area EA2. In one or more embodiments, the width of the second emission area EA2 may become less than the width of the second drop area JA2, which may be advantageous or beneficial for realizing or providing relatively high resolution of the display device 10.

Each of the bank portion BNK and the light transmitting portion LTP may have a hydrophobic surface (e.g., a surface having a water-repelling property and/or a water-resistant property), and the light transmitting portion LTP may have an inclined top surface between the first bank BN1 and the fourth bank BN4. Because the second ink material INK2 has a hydrophilic property (e.g., a high affinity for water), a part of the second ink material INK2 dropped on the light transmitting portion LTP and the fourth bank BN4 in the second drop area JA2 may relatively easily flow in the flow direction FD toward the second emission area EA2 due to the hydrophobic property (e.g., a water-repelling property and/or a water-resistant property) of the surface of each of the bank portion BNK and the light transmitting portion LTP and the inclined top surface of the light transmitting portion LTP.

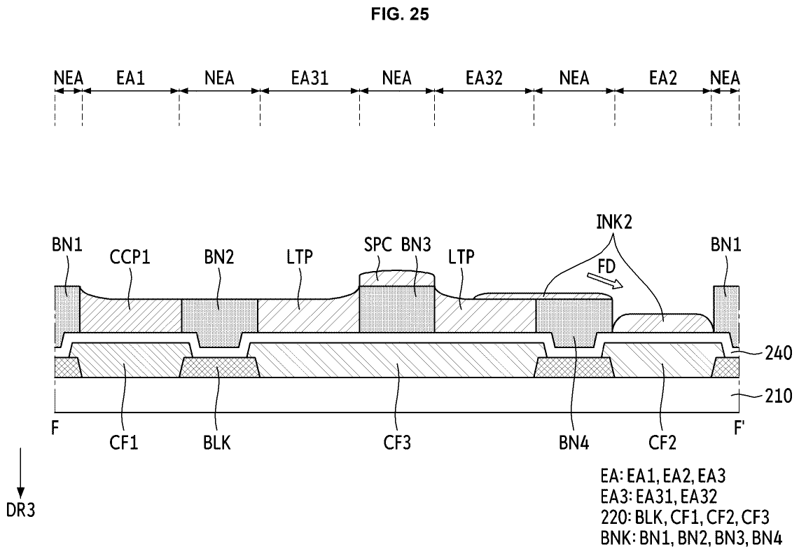

In one or more embodiments, as illustrated in FIG. 25, a part of the second ink material INK2 dropped in an area of the second drop area JA2 other than the second emission area EA2 may flow along the flow direction FD, and thus may be in the second emission area EA2.

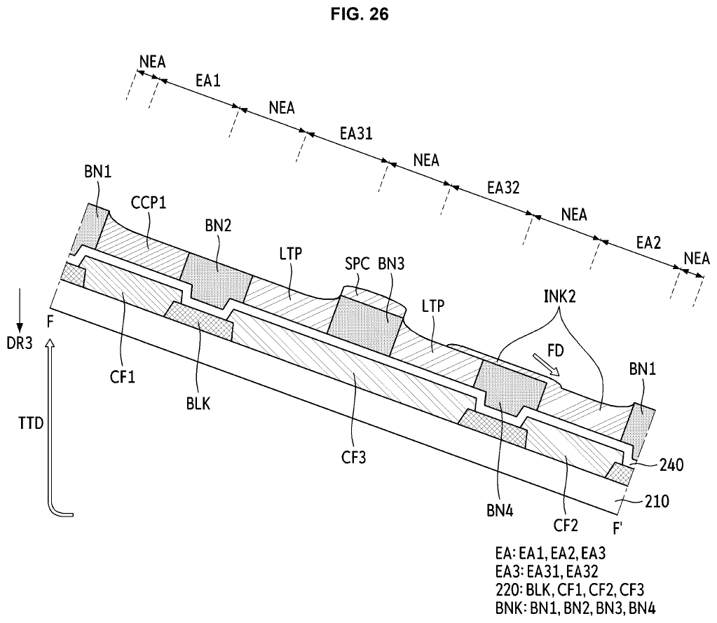

According to one or more embodiments, as illustrated in FIG. 26, in a step (e.g., act or task) of causing a part of the second ink material INK2 to flow, the second support substrate 210 may be tilted in a tilting direction TTD that increases the inclination of the flow direction FD.

For example, the tilting angle of the second support substrate 210 may be about 15 degrees or more.

In one or more embodiments, the fluidity of a part of the second ink material INK2 may be increased, so that a defect in which a part of the second ink material INK2 remains in an area of the second drop area JA2 other than the second emission area EA2 may be prevented (or a degree or occurrence of such defect may be reduced).

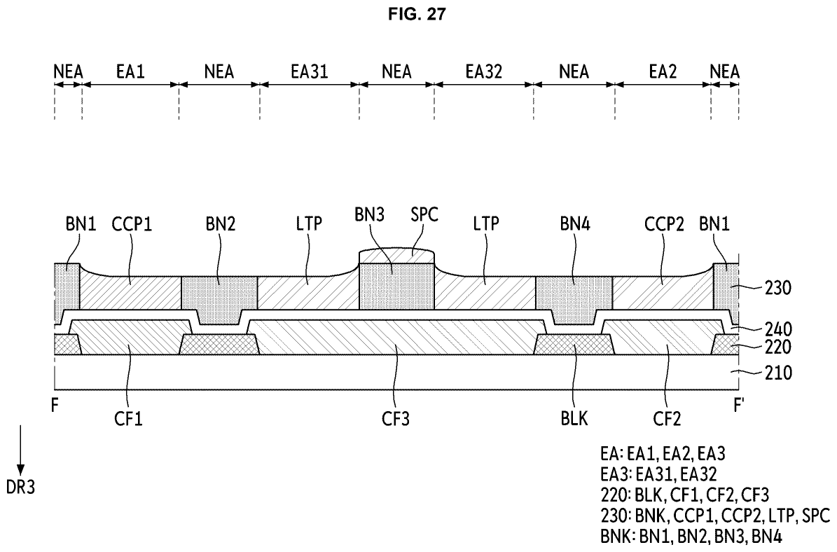

As illustrated in FIG. 27, the second color conversion portion CCP2 may be provided by curing the second ink material INK2 in the second emission area EA2.

In one or more embodiments, the color conversion layer 230 including the light transmitting portion LTP, the first color conversion portion CCP1, the second color conversion portion CCP2, and the spacer SPC may be provided.

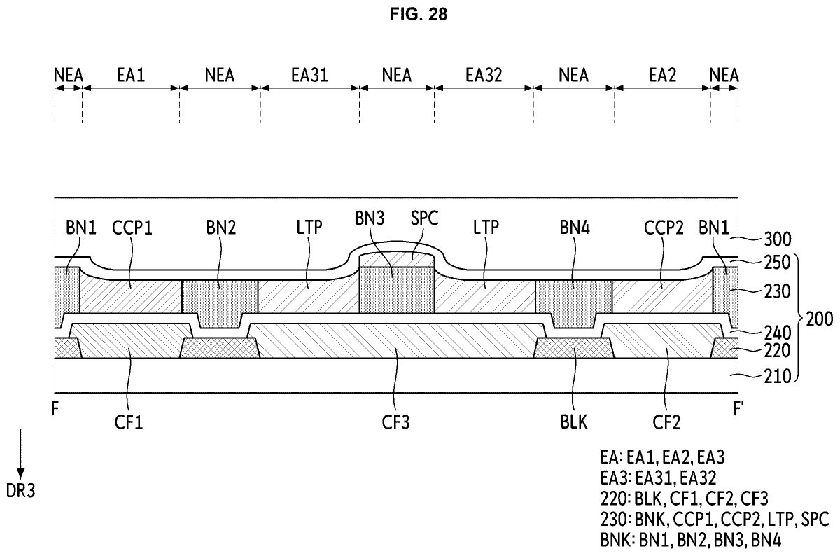

As illustrated in FIG. 28, in step (e.g., act or task) S24 of providing the second capping layer 250, the second capping layer 250 may be provided by stacking an inorganic insulating (e.g., electrically insulating) material that covers the color conversion layer 230.

Further, in step (e.g., act or task) S30 of providing the filling layer 300, the filling layer 300 may be provided by dropping a filling material on the second capping layer 250 and diffusing it.

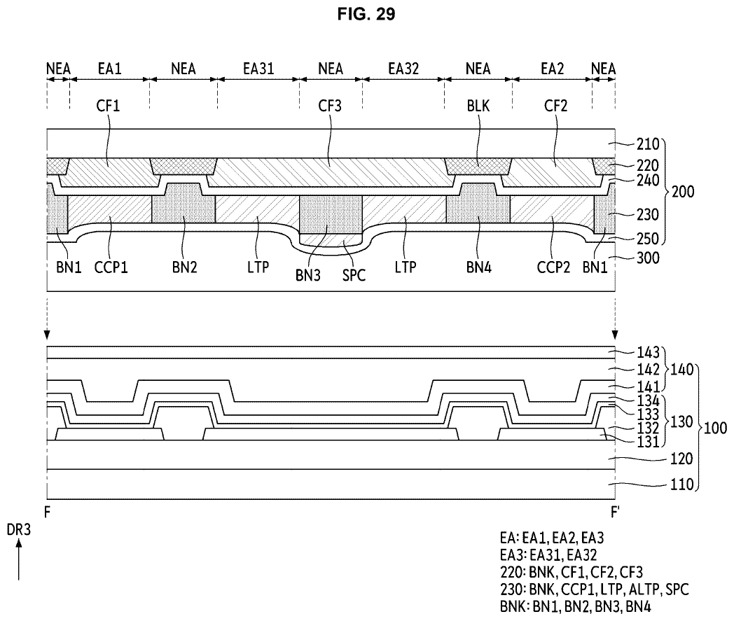

As illustrated in FIG. 29, in step (e.g., act or task) S40 of aligning and bonding the first substrate 100 and the second substrate 200, the first substrate 100 and the second substrate 200 may be aligned in a direction in which the second capping layer 250 and the encapsulation layer 140 are opposite to (e.g., face) each other.

As illustrated in FIG. 9, the first substrate 100 and the second substrate 200 may be bonded in a state where the filling layer 300 is between the first substrate 100 and the second substrate 200.

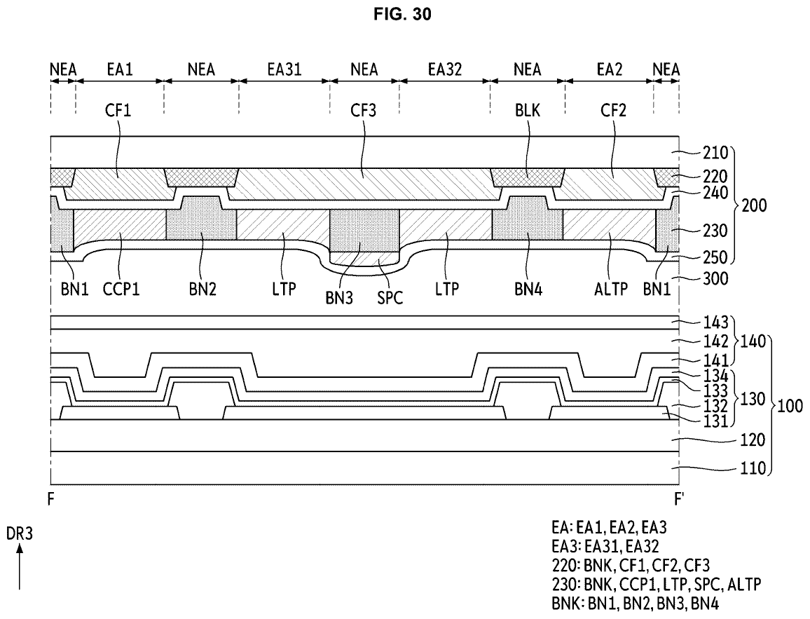

In one or more embodiments, in consideration of the light emission efficiency of the second emission area EA2, the color conversion layer 230 may include an additional light transmitting portion ALTP (see FIG. 30) instead of the second color conversion portion CCP2.

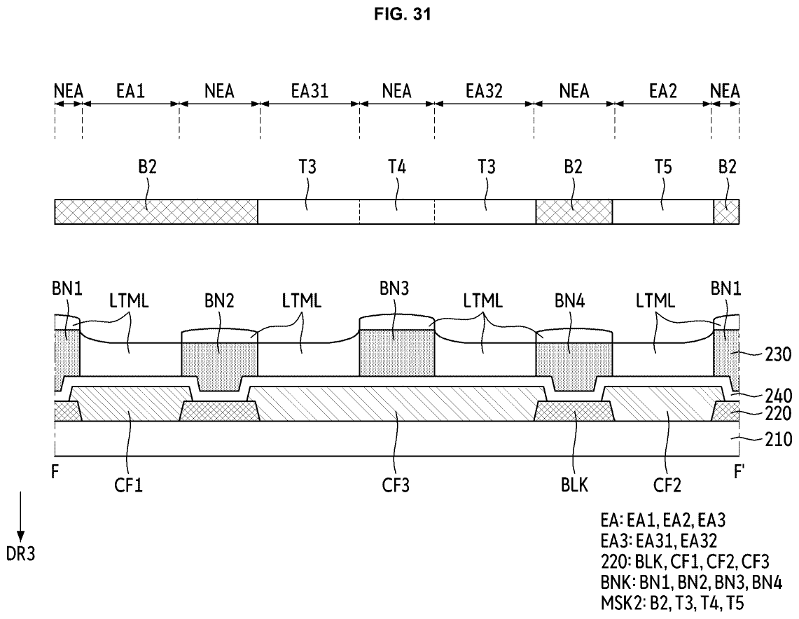

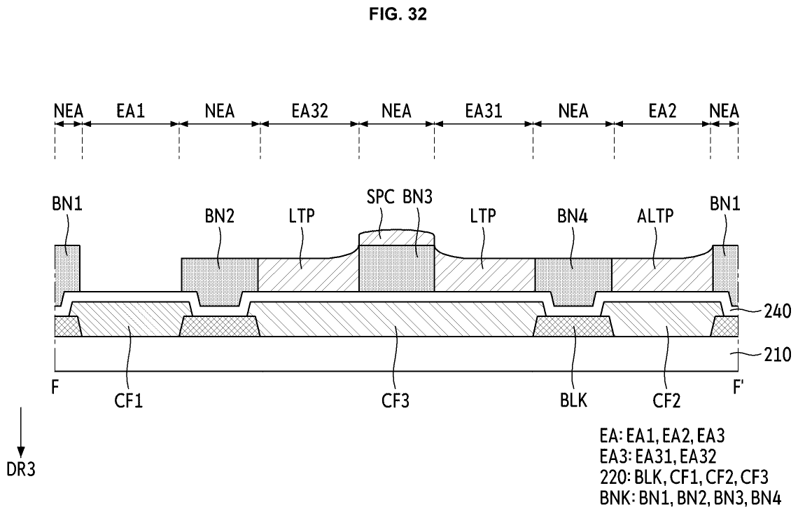

FIG. 30 is a cross-sectional view taken along the line F-F′ of FIG. 3 according to one or more embodiments. FIGS. 31 and 32 are process views illustrating one or more steps (e.g., acts or tasks) of FIG. 12 according to one or more embodiments of FIG. 30.

The display device 10 of one or more embodiments illustrated in FIG. 30 may be substantially the same as the display device 10 of one or more embodiments illustrated in FIGS. 1 to 9 except that the color conversion layer 230 may not include the second color conversion portion CCP2 but may include the additional light transmitting portion ALTP, so that the redundant description may not be provided.

According to one or more embodiments illustrated in FIG. 30, the color conversion layer 230 may include the additional light transmitting portion ALTP that is in the second emission area EA2 and that is to transmit light of the fourth wavelength band emitted from the light emitting element LE.

In one or more embodiments, light loss caused by the second color conversion portion CCP2 may be prevented (or a degree or occurrence of light loss caused by the second color conversion portion CCP2 may be reduced), so that the luminance of the second emission area EA2 may be improved or enhanced. Further, the ejection step (e.g., act or task) of the second ink material INK2 to provide the second color conversion portion CCP2, the flow step (e.g., act or task) of the second ink material INK2, and the curing step (e.g., act or task) of the second ink material INK2 may not be provided, so that the manufacturing process of the display device 10 may be simplified.

As illustrated in FIG. 31, according to one or more embodiments illustrated in FIG. 30, in step (e.g., act or task) S232 of providing the light transmitting portion LTP, the second mask MSK2 may further include a fifth transmitting portion T5 that is opposite to (e.g., faces) the second emission area EA2.

In one or more embodiments, as illustrated in FIG. 32, in the step (e.g., act or task) of developing the light transmitting material layer LTML, the additional light transmitting portion ALTP may be provided by a part of the light transmitting material layer LTML that is opposite to (e.g., faces) the fifth transmitting portion T5.

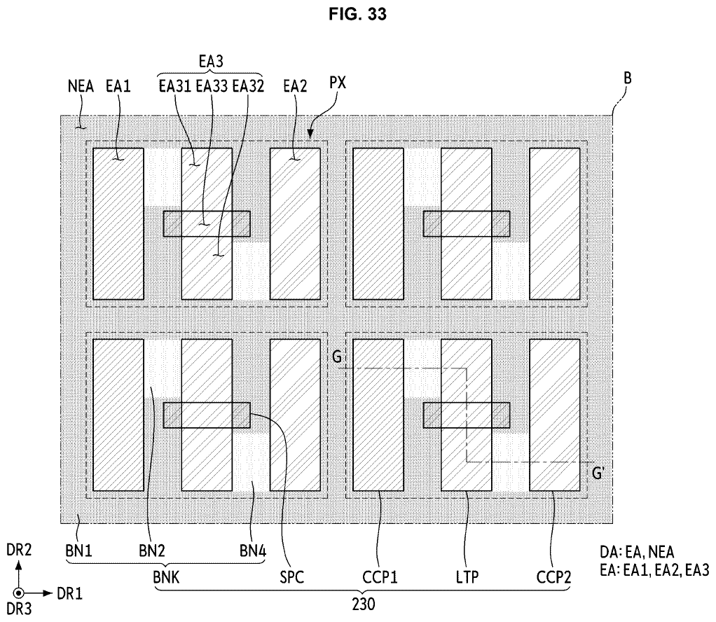

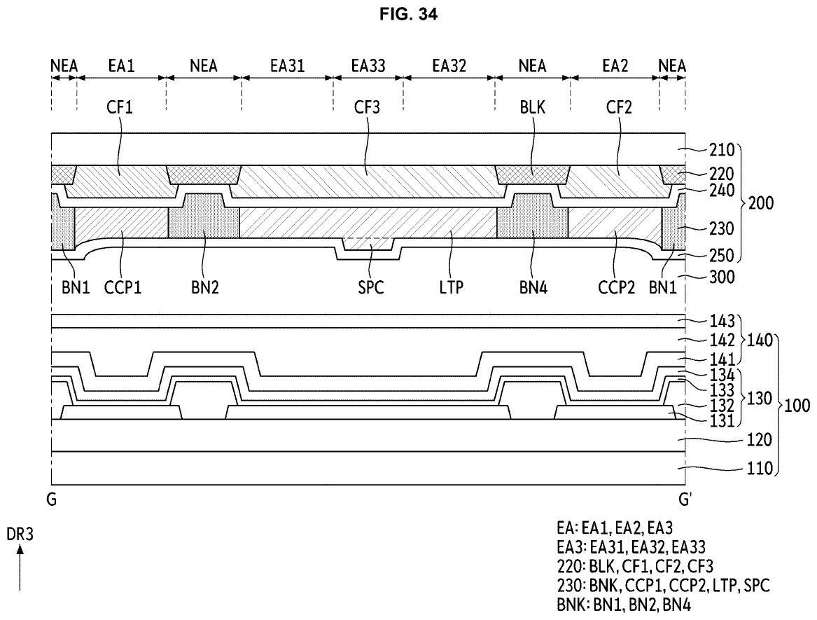

FIG. 33 is a plan view illustrating a display area and a color conversion layer of part B of FIG. 1 according to one or more embodiments. FIG. 34 is a cross-sectional view taken along the line G-G′ of FIG. 33.

The display device 10 of one or more embodiments illustrated in FIGS. 33 and 34 may be substantially the same as the display device 10 of one or more embodiments illustrated in FIGS. 1 to 9 and 30 except that the third emission area EA3 may further include a third divided area EA33 between the first divided area EA31 and the second divided area EA32 and that the spacer SPC may be on a part of the third divided area EA33 in the light transmitting portion LTP, so that the redundant description may not be provided.

As illustrated in FIGS. 33 and 34, according to one or more embodiments, the spacer SPC may not be on the third bank BN3 but on the light transmitting portion LTP.

The spacer SPC may extend to the first bank BN1 along the first direction DR1.

In one or more embodiments, the reduction in the aperture ratio due to the arrangement of the spacer SPC may be prevented (or a degree or occurrence of the reduction in the aperture ratio due to the arrangement of the spacer SPC may be reduced), so that the luminance deterioration may be suppressed (or a degree or occurrence of the luminance deterioration may be reduced).

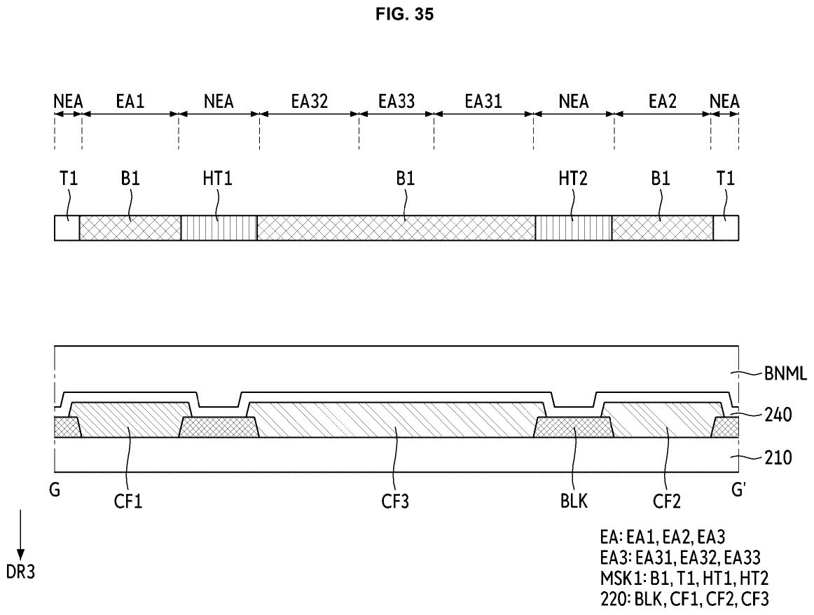

FIGS. 35, 36, 37, 38, and 39 are process views illustrating one or more steps (e.g., acts or tasks) of FIG. 12 according to one or more embodiments of FIGS. 33 and 34.

As illustrated in FIG. 35, according to one or more embodiments illustrated in FIGS. 33 and 34, in step (e.g., act or task) S231 of providing the bank portion BNK, the first blocking portion B1 of the first mask MSK1 may be opposite to (e.g., may face) the third emission area EA3 including the first divided area EA31, the second divided area EA32, and the third divided area EA33.

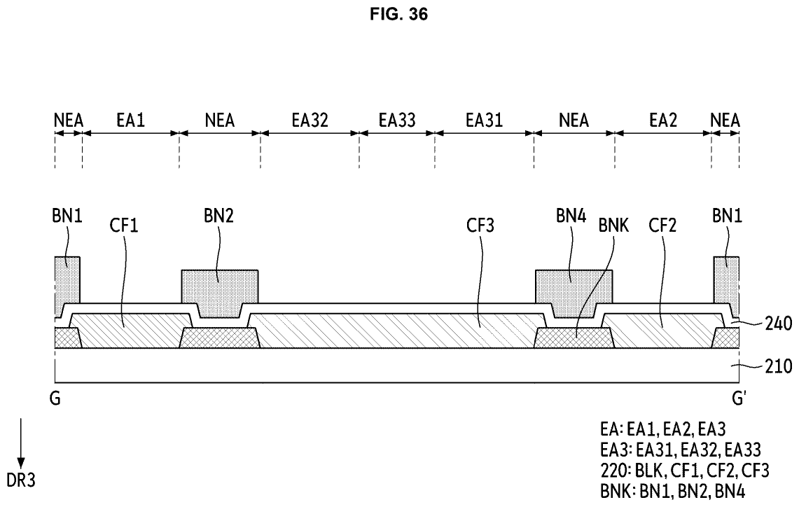

In one or more embodiments, as illustrated in FIG. 36, the bank portion BNK may not include (e.g., may exclude) the third bank BN3 between the first divided area EA31 and the second divided area EA32.

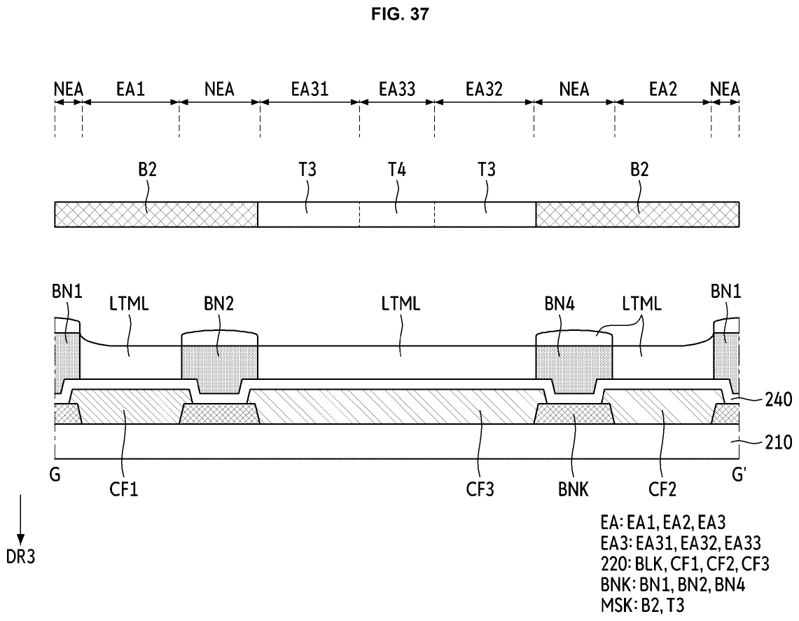

Further, as illustrated in FIG. 37, according to one or more embodiments illustrated in FIGS. 33 and 34, in step (e.g., act or task) S232 of providing the light transmitting portion LTP, the third transmitting portion T3 of the second mask MSK2 may be opposite to (e.g., may face) the third emission area EA3 including the first divided area EA31, the second divided area EA32, and the third divided area EA33.

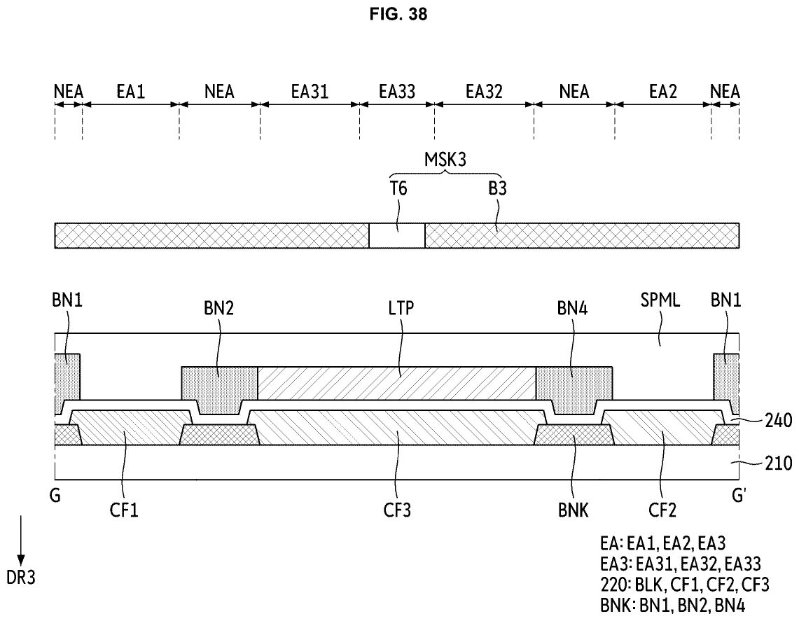

In one or more embodiments, as illustrated in FIG. 38, the light transmitting portion LTP may be in the first divided area EA31, the second divided area EA32, and the third divided area EA33.

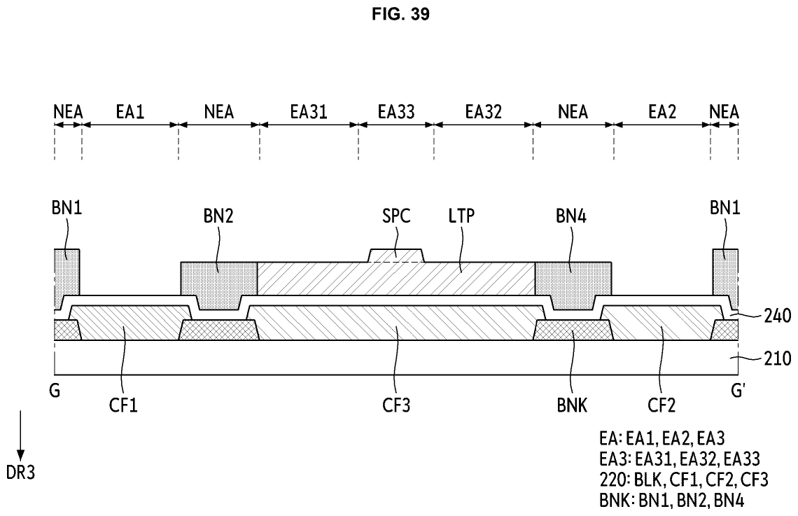

As illustrated in FIGS. 38 and 39, according to one or more embodiments illustrated in FIGS. 33 and 34, step (e.g., act or task) S23 of providing the color conversion layer 230 may further include a step (e.g., act or task) of providing the spacer SPC after step (e.g., act or task) S232 of providing the light transmitting portion LTP.

The step (e.g., act or task) of providing the spacer SPC may include a step (e.g., act or task) of removing the remaining part of a spacer material layer SPML that covers the light transmitting portion LTP except a part of the remaining part of the spacer material layer SPML that overlaps the third divided area EA33.

For example, the step (e.g., act or task) of providing the spacer SPC may include a step (e.g., act or task) of exposing the spacer material layer SPML that covers the light transmitting portion LTP by utilizing a third mask MSK3, and a step (e.g., act or task) of developing the spacer material layer SPML.

As illustrated in FIG. 38, in the step (e.g., act or task) of exposing the spacer material layer SPML, the third mask MSK3 may include a third blocking portion B3 that is to block light and a sixth transmitting portion T6 that is opposite to (e.g., faces) the third divided area EA33.

The sixth transmitting portion T6 may extend in the first direction DR1 and may further be opposite to (e.g., may further face) a part of the first bank BN1.

As illustrated in FIG. 39, in the step (e.g., act or task) of developing the spacer material layer SPML, the spacer SPC may be provided by a part of the spacer material layer SPML that is opposite to (e.g., faces) the sixth transmitting portion T6. Further, the remaining part of the spacer material layer SPML that is opposite to (e.g., faces) the third blocking portion B3 may be removed by a developer.

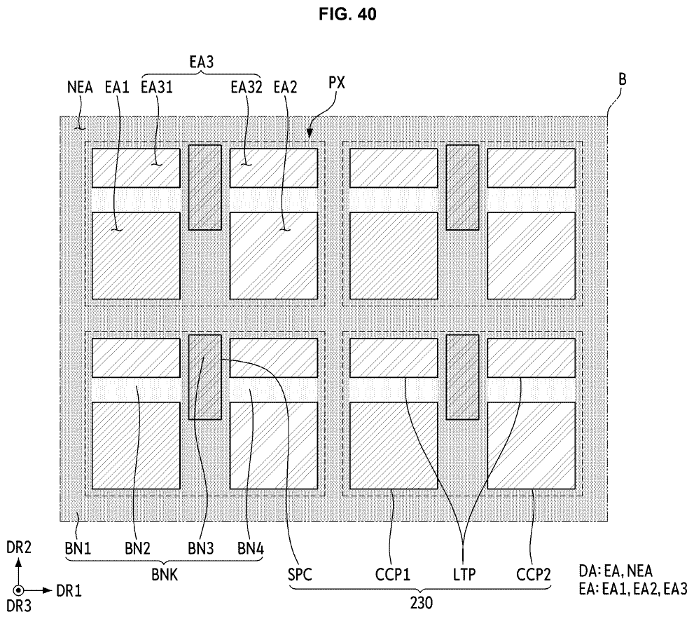

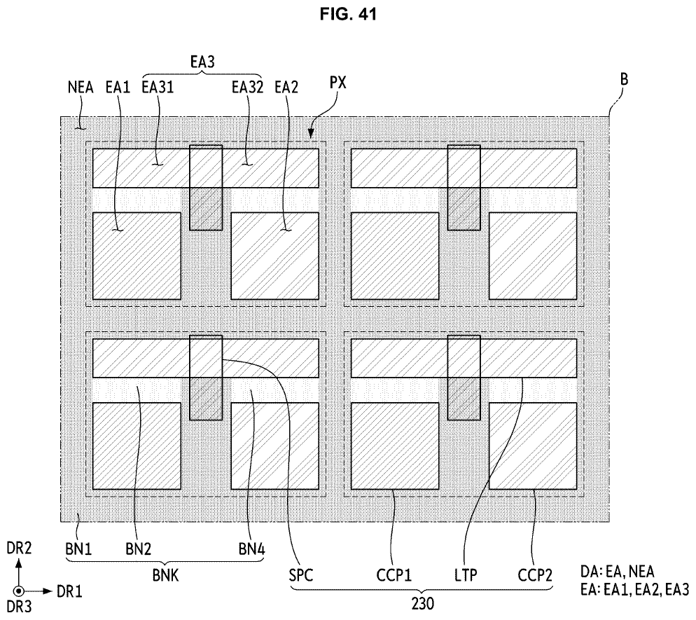

FIGS. 40 and 41 are plan views illustrating a display area and a color conversion layer of part B of FIG. 1 according to one or more embodiments.

The display device 10 of one or more embodiments illustrated in FIG. 40 may be substantially the same as the display device 10 of one or more embodiments illustrated in FIGS. 1 to 9 and 30, except that the third emission area EA3 may be opposite to (e.g., may face) the first emission area EA1 and the second emission area EA2 not in the first direction DR1 but in the second direction DR2, so that the redundant description may not be provided.

According to one or more embodiments illustrated in FIG. 40, in the first direction DR1 that crosses (e.g., intersects) the second direction DR2 in which the first emission area EA1 and the third emission area EA3 are opposite to (e.g., face) each other, the first emission area EA1 and the second emission area EA2 may be adjacent to each other.

Further, in the second direction DR2 in which the first emission area EA1 and the third emission area EA3 are opposite to (e.g., face) each other, the third emission area EA3 may further be opposite to (e.g., may further face) the second emission area EA2.

The display device 10 of one or more embodiments illustrated in FIG. 41 may be substantially the same as the display device 10 of one or more embodiments illustrated in FIG. 40, except that the third emission area EA3 may further include the third divided area EA33 between the first divided area EA31 and the second divided area EA32 and that the spacer SPC may be on a part of the third divided area EA33 in the light transmitting portion LTP, so that the redundant description may not be provided.

The display device 10 of one or more embodiments illustrated in FIG. 41 may be substantially the same as the display device 10 of one or more embodiments illustrated in FIGS. 33 and 34, except that the third emission area EA3 may further include the third divided area EA33 between the first divided area EA31 and the second divided area EA32 and that the spacer SPC may be on a part of the third divided area EA33 in the light transmitting portion LTP, so that the redundant description may not be provided.

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

A display device, a device for manufacturing substantially the same and/or any other relevant devices or components according to embodiments of the present invention described herein may be implemented utilizing any suitable hardware, firmware (e.g., an application-specific integrated circuit), software, or a combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

A person of ordinary skill in the art, in view of the present disclosure in its entirety, would appreciate that each suitable feature of the one or more embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

However, the aspects, features, and/or embodiments of the present disclosure are not restricted to the one set forth herein. The above and other aspects, features, and/or embodiments of the present disclosure will become more apparent to one of daily skill in the art to which the present disclosure pertains by referencing the appended claims and equivalents thereof.

What is claimed is:

1. A display device, comprising:
a first substrate comprising light emitting elements in emission areas on a first support substrate;
a second substrate that is opposite to the first substrate; and
a filling layer between the first substrate and the second substrate,
wherein the emission areas comprise:
a first emission area that is to emit light of a first wavelength band;
a second emission area that is to emit light of a second wavelength band, the second wavelength band being lower than the first wavelength band; and
a third emission area that is to emit light of a third wavelength band, the third wavelength band being lower than the second wavelength band,
wherein the light emitting elements are to emit light of a fourth wavelength band, the fourth wavelength band being lower than or equal to the third wavelength band,
wherein the second substrate comprises:
a second support substrate that is opposite to the first substrate;
a color filter layer on one surface of the second support substrate; and
a color conversion layer on the color filter layer,
wherein the color conversion layer comprises a bank portion in a non-emission area between the emission areas, and
wherein the bank portion comprises:
a first bank having a first thickness; and
a second bank having a second thickness that is less than the first thickness in at least a part of the non-emission area between the first emission area and the third emission area.

2. The display device as claimed in claim 1, wherein the color filter layer comprises:
a light blocking portion in the non-emission area, the light blocking portion being to block light;
a first filter portion in the first emission area, the first filter portion being to transmit the light of the first wavelength band;
a second filter portion in the second emission area, the second filter portion being to transmit the light of the second wavelength band; and
a third filter portion in the third emission area, the third filter portion being to transmit the light of the third wavelength band,
wherein the color conversion layer further comprises:
a first color conversion portion in the first emission area, the first color conversion portion being to convert the light of the fourth wavelength band into light of the first wavelength band; and
a light transmitting portion in at least a part of the third emission area, the light transmitting portion being to transmit the light of the fourth wavelength band,
wherein the bank portion is around a periphery of each of the first color conversion portion and the light transmitting portion,
wherein a part of the light transmitting portion between the first bank and the second bank has a thickness that varies from the first thickness to the second thickness, and
wherein a surface of each of the light transmitting portion and the bank portion has a hydrophobic property.

3. The display device as claimed in claim 2, wherein the third emission area comprises a first divided area on one side and a second divided area on the other side in a direction that crosses a direction in which the first emission area and the third emission area are opposite to each other, and
wherein the second bank is between the first emission area and the first divided area.

4. The display device as claimed in claim 3, wherein the color conversion layer further comprises a spacer that extends in the direction in which the first emission area and the third emission area are opposite to each other and that crosses the third emission area,
the first divided area is adjacent to one side of the spacer, and
the second divided area is adjacent to the other side of the spacer.

5. The display device as claimed in claim 4, wherein the bank portion further comprises a third bank having the first thickness between the first divided area and the second divided area, and
the spacer is on the first bank and the third bank.

6. The display device as claimed in claim 4, wherein the third emission area further comprises a third divided area between the first divided area and the second divided area, and
the spacer is on a part of the third divided area in the light transmitting portion.

7. The display device as claimed in claim 3, wherein the color conversion layer further comprises a second color conversion portion in the second emission area, the second color conversion portion being to convert the light of the fourth wavelength band into light of the second wavelength band,
wherein the bank portion further comprises a fourth bank having the second thickness between the second emission area and the second divided area, and
wherein a part of the light transmitting portion between the first bank and the fourth bank has a thickness that varies from the first thickness to the second thickness.

8. The display device as claimed in claim 3, wherein the color conversion layer further comprises an additional light transmitting portion in the second emission area, the additional light transmitting portion being to transmit the light of the fourth wavelength band, and
wherein a surface of the additional light transmitting portion has a hydrophobic property.

9. The display device as claimed in claim 3, wherein in the direction in which the first emission area and the third emission area are opposite to each other, the third emission area is between the first emission area and the second emission area.

10. The display device as claimed in claim 4, wherein in the direction that crosses the direction in which the first emission area and the third emission area are opposite to each other, the first emission area and the second emission area are adjacent to each other, and
wherein in the direction in which the first emission area and the third emission area are opposite to each other, the third emission area is further opposite to the second emission area.

11. The display device as claimed in claim 2, wherein the second substrate further comprises:
a first capping layer that covers the color filter layer; and
a second capping layer that covers the color conversion layer.

12. The display device as claimed in claim 2, wherein the first substrate comprises:
a circuit layer on the first support substrate, the circuit layer comprising light emitting pixel drivers that are electrically connected to the light emitting elements, respectively;
an element layer on the circuit layer, the element layer comprising the light emitting elements; and
an encapsulation layer that covers the element layer,
wherein the element layer comprises:
anode electrodes in the emission areas;
a pixel defining layer in the non-emission area, the pixel defining layer covering an edge of the anode electrodes;
a light emitting layer on the anode electrodes and the pixel defining layer; and
a cathode electrode on the light emitting layer, and
wherein each of the light emitting elements comprises a structure in which a light emitting layer is between an anode electrode of the anode electrodes and the cathode electrode that are opposite to each other.

13. A method comprising:
preparing a first substrate comprising light emitting elements in emission areas;
preparing a second substrate comprising a color filter layer and a color conversion layer;
providing a filling layer on the first substrate or the second substrate; and
aligning and bonding the first substrate and the second substrate,
wherein the preparing of the second substrate comprises:
providing the color filter layer on a second support substrate;
providing a first capping layer that covers the color filter layer;
providing the color conversion layer on the first capping layer; and
providing a second capping layer that covers the color conversion layer,
wherein the providing of the color conversion layer comprises:
providing a bank portion in a non-emission area between the emission areas,
wherein the providing of the bank portion comprises:
exposing a bank material layer on the first capping layer by utilizing a first mask; and
developing the bank material layer,
wherein in the exposing of the bank material layer, the first mask comprises:
a first blocking portion that is opposite to the emission areas;
a first transmitting portion that is opposite to a part of the non-emission area, the first transmitting portion being to transmit light; and
a first semi-transmitting portion that is opposite to another part of the non-emission area, the first semi-transmitting portion being to transmit a smaller amount of light than the first transmitting portion, and
wherein in the developing of the bank material layer, the bank portion having a hydrophobic surface is provided,
wherein the bank portion comprises:
a first bank that is opposite to the first transmitting portion, the first bank having a first thickness; and
a second bank that is opposite to the first semi-transmitting portion, he second bank having a second thickness that is less than the first thickness, and
wherein the method is a method for manufacturing a display device.

14. The method as claimed in claim 13, wherein the emission areas comprise:
a first emission area that is to emit light of a first wavelength band;
a second emission area that is to emit light of a second wavelength band, the second wavelength band being lower than the first wavelength band; and
a third emission area that is to emit light of a third wavelength band, the third wavelength band being lower than the second wavelength band,
wherein the third emission area comprises a first divided area on one side and a second divided area on the other side in a direction that crosses a direction in which the first emission area and the third emission area are opposite to each other,
wherein the light emitting elements are to emit light of a fourth wavelength band, the fourth wavelength band being lower than or equal to the third wavelength band,
wherein in the providing of the color filter layer, the color filter layer comprises:
a light blocking portion in the non-emission area, the light blocking portion being to block light;
a first filter portion in the first emission area, the first filter portion being to transmit the light of the first wavelength band;
a second filter portion in the second emission area, the second filter portion being to transmit the light of the second wavelength band; and
a third filter portion in the third emission area, the third filter portion being to transmit the light of the third wavelength band,
wherein in the providing of the bank portion, the second bank is between the first emission area and the first divided area,
wherein the providing of the color conversion layer comprises:
providing a light transmitting portion that is to transmit the light of the fourth wavelength band in the third emission area; and
providing a first color conversion portion that is to convert the light of the fourth wavelength band into light of the first wavelength band in the first emission area, and
wherein in the providing of the light transmitting portion, a part of the light transmitting portion between the first bank and the second bank has an inclined top surface.

15. The method as claimed in claim 14, wherein in the providing of the light transmitting portion, a surface of the light transmitting portion has a hydrophobic property, and
wherein the providing of the first color conversion portion comprises:
dropping a first ink material in a first drop area comprising a part of the first emission area that is adjacent to one side of the second bank, the first divided area, and the second bank;
causing a part of the first ink material dropped on the second bank and the light transmitting portion to flow to the first emission area due to the inclined top surface of the light transmitting portion and a hydrophobic property of a surface of each of the second bank and the light transmitting portion; and
providing the first color conversion portion by curing the first ink material in the first emission area.

16. The method as claimed in claim 15, wherein in the causing of the part of the first ink material to flow to the first emission area, the second support substrate is tilted.

17. The method as claimed in claim 14, wherein in the providing of the bank portion,
the first mask further comprises a second transmitting portion that extends in the direction in which the first emission area and the third emission area are opposite to each other and that crosses the third emission area,
the bank portion further comprises a third bank that is opposite to the second transmitting portion and that has the first thickness,
the first divided area is adjacent to one side of the third bank, and
the second divided area is adjacent to the other side of the third bank,
wherein the providing of the light transmitting portion comprises:
exposing a light transmitting material layer that covers the first capping layer and the bank portion by utilizing a second mask; and
developing the light transmitting material layer,
wherein in the exposing of the light transmitting material layer, the second mask comprises:
a second blocking portion that is opposite to the first emission area, the second emission area, and the non-emission area, the second block portion being to block light;
a third transmitting portion that is opposite to the first divided area and the second divided area; and
a fourth transmitting portion that is opposite to the third bank, and wherein in the developing of the light transmitting material layer,
the light transmitting portion that is opposite to the third transmitting portion and a spacer that is opposite to the fourth transmitting portion are provided, and
each of the light transmitting portion and the spacer has a hydrophobic surface.

18. The method as claimed in claim 14, wherein in the providing of the bank portion,
the first mask further comprises a second semi-transmitting portion that is opposite to a part of the non-emission area between the second emission area and the second divided area, and
the bank portion further comprises a fourth bank that is opposite to the second semi-transmitting portion and that has the second thickness,
wherein the providing of the color conversion layer further comprises providing a second color conversion portion that is to convert the light of the fourth wavelength band into light of the second wavelength band in the second emission area,
wherein in the providing of the light transmitting portion, another part of the light transmitting portion between the first bank and the fourth bank has an inclined top surface, and
wherein the providing of the second color conversion portion comprises:
dropping a second ink material in a second drop area comprising a part of the second emission area that is adjacent to one side of the fourth bank, the second divided area, and the fourth bank;
causing a part of the second ink material dropped on the fourth bank and the light transmitting portion to flow to the second emission area due to the inclined top surface of the light transmitting portion and a hydrophobic property of a surface of each of the fourth bank and the light transmitting portion; and
providing the second color conversion portion by curing the second ink material in the second emission area.

19. An electronic device, comprising a display device comprising:
a first substrate comprising light emitting elements in emission areas on a first support substrate;
a second substrate that is opposite to the first substrate; and
a filling layer between the first substrate and the second substrate,
wherein the emission areas comprise:
a first emission area that is to emit light of a first wavelength band;
a second emission area that is to emit light of a second wavelength band, the second wavelength band being lower than the first wavelength band; and
a third emission area that is to emit light of a third wavelength band, the third wavelength band being lower than the second wavelength band,
wherein the light emitting elements are to emit light of a fourth wavelength band, the fourth wavelength band being lower than or equal to the third wavelength band,
wherein the second substrate comprises:
a second support substrate that is opposite to the first substrate;
a color filter layer on one surface of the second support substrate; and
a color conversion layer on the color filter layer,
wherein the color conversion layer comprises a bank portion in a non-emission area between the emission areas, and
wherein the bank portion comprises:
a first bank having a first thickness; and
a second bank having a second thickness that is less than the first thickness in at least a part of the non-emission area between the first emission area and the third emission area.

20. The electronic device as claimed in claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
